(19) United States
(12) Patent Application Publication
(10) Pub. No.: US 2022/0181174 A1
(43) Pub. Date: Jun. 9, 2022

(54) WAFER MANUFACTURING APPARATUS

(71) Applicant: DISCO CORPORATION, Tokyo (JP)

(72) Inventors: Ryohei YAMAMOTO, Tokyo (JP); Kazuya HIRATA, Tokyo (JP)

(21) Appl. No.: 17/457,706

(22) Filed: Dec. 6, 2021

(30) Foreign Application Priority Data
Dec. 7, 2020 (JP) 2020-202552

(51) Int. Cl. H01L 21/67; H01L 21/677; B23K 26/035; H04N 5/225

(52) U.S. Cl. CPC H01L 21/67092; H01L 21/67736; H01L 2221/68386; H04N 5/2257; B23K 26/037

(57) ABSTRACT

A wafer manufacturing apparatus includes an ingot grinding unit for grinding an upper surface of an ingot to planarize the upper surface of the ingot, a laser applying unit for forming peel-off layers in the ingot at a depth therein, which corresponds to the thickness of a wafer to be produced from the ingot, from the upper surface of the ingot, a wafer peeling unit for holding the upper surface of the ingot and peeling off a wafer from the ingot at the peel-off layers, a tray having an ingot support portion and a wafer support portion, and a belt conveyor unit for delivering the ingot supported on the tray between the ingot grinding unit, the laser applying unit, and the wafer peeling unit.

### BACKGROUND OF THE INVENTION

### Field of the Invention

The present invention relates to a wafer manufacturing apparatus for manufacturing wafers from a semiconductor ingot.

### Description of the Related Art

Devices such as integrated circuits (ICs), large scale integration (LSI) circuits, and light emitting diodes (LEDs) are formed by layering a functional layer on a face side of a wafer made of a material such as silicon (Si) or sapphire (AL₂O₃) and demarcating a plurality of areas on the functional layer with a plurality of crossing projected dicing lines thereon. Power devices, LEDs, etc. are formed by layering a functional layer on a face side of a wafer made of a material such as single-crystal silicon carbide (SiC) and demarcating a plurality of areas on the functional layer with a plurality of crossing projected dicing lines thereon. The wafer with the devices formed thereon is divided along the projected dicing lines into individual device chips by a cutting apparatus or a laser processing apparatus. The device chips that include the respective devices will be used in electric appliances such as mobile phones and personal computers.

Wafers on which to form devices are generally produced by cutting a cylindrical semiconductor ingot into thin slices with a wire saw. Face and reverse sides of the slices or wafers sliced from the ingot are polished to a mirror finish (see, for example, JP2000-94221A). However, it is uneconomical to slice a semiconductor ingot into wafers with a wire saw and polish the face and reverse sides of the wafers because much of the semiconductor ingot, e.g., 70% to 80% thereof, is wasted. Particularly, single-crystal SiC ingots are disadvantageous in that they are of poor productivity as they are hard, difficult and time-consuming to cut with a wire saw, and their unit cost is so high that they fail to produce wafers efficiently.

There has been proposed in the art a technology in which a laser beam having a wavelength transmittable through single-crystal SiC is applied to a single-crystal SiC ingot while positioning a focused spot of the laser beam within the single-crystal SiC ingot, thereby forming peel-off layers in a projected severance plane in the SiC ingot, and then a wafer is peeled off from the single-crystal SiC ingot along the projected severance plane where the peel-off layers are formed (see, for example, JP2020-72098A).

JP2020-72098A also discloses a technology for efficiently performing a series of operations for placing several, e.g., four, delivery trays housing ingots at all times on a belt conveyor, delivering the ingots in the delivery trays to processing units that manufacture wafers from the ingots, accommodating the manufactured wafers in the same delivery trays that has housed the ingots, and then accommodating the wafers in cassettes that are linked to the ingots in a wafer unloading area.

### SUMMARY OF THE INVENTION

Semiconductor ingots have upper surfaces planarized by grinding means. Occasionally, however, the upper surfaces of the semiconductor ingots may not sufficiently be planarized even by the grinding means. In the case where the upper surface of a semiconductor ingot is not sufficiently planarized, a laser beam applied to form peel-off layers in the semiconductor ingot is not focused at an adequate position in the semiconductor ingot, with the result that a wafer peeled off from the semiconductor ingot may be reduced in quality.

It is therefore an object of the present invention to provide a wafer manufacturing apparatus that is capable of preventing wafers peeled off from a semiconductor ingot from being reduced in quality.

In accordance with an aspect of the present invention, there is provided a wafer manufacturing apparatus for manufacturing a wafer from a semiconductor ingot, including an ingot grinding unit, a laser applying unit, a wafer peeling unit, a tray, a belt conveyor unit, and a quality inspecting unit. The ingot grinding unit includes a first holding table for holding the semiconductor ingot thereon and grinding means for grinding an upper surface of the semiconductor ingot held on the first holding table to planarize the upper surface of the semiconductor ingot. The laser applying unit includes a second holding table for holding the semiconductor ingot thereon and laser applying means for applying a laser beam having a wavelength transmittable through the semiconductor ingot while positioning a focused spot of the laser beam at a depth in the ingot, the depth corresponding to the thickness of the wafer to be produced from the semiconductor ingot, from the upper surface of the semiconductor ingot held on the second holding table, thereby forming peel-off layers in the semiconductor ingot. The wafer peeling unit includes a third holding table for holding the semiconductor ingot thereon and wafer peeling means for holding the upper surface of the semiconductor ingot held on the third holding table and peeling an ingot portion as the wafer from the ingot at the peel-off layers. The tray includes an ingot support portion for supporting the semiconductor ingot and a wafer support portion for supporting the wafer that has been peeled off from the semiconductor ingot. The belt conveyor unit delivers the semiconductor ingot supported on the tray between the ingot grinding unit, the laser applying unit, and the wafer peeling unit. The quality inspecting unit is disposed adjacent to the belt conveyor unit.

Preferably, the quality inspecting unit may include an illuminating device, image capturing means for detecting reflected light reflected by an upper surface of the wafer that is illuminated by light emitted from the illuminating device, and defect detecting means for processing an image captured by the image capturing means and detecting a defect from the processed image. Preferably, the quality inspecting unit may include an illuminating device, image capturing means for detecting reflected light reflected by an upper surface of the semiconductor ingot that is illuminated by light emitted from the illuminating device, and defect detecting means for processing an image captured by the image capturing means and detecting a defect from the processed image.

Since the wafer manufacturing apparatus according to the present invention includes the quality inspecting unit disposed adjacent to the belt conveyor unit, the quality of the wafer manufactured from the semiconductor ingot is prevented from being lowered.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of a wafer manufacturing apparatus according to an embodiment of the present invention;

FIG. 2 is a perspective view of an ingot grinding unit illustrated in FIG. 1;

FIG. 3 is an enlarged fragmentary perspective view of the ingot grinding unit illustrated in FIG. 2;

FIG. 4 is a perspective view of a laser applying unit illustrated in FIG. 1;

FIG. 5 is a block diagram of the laser applying unit illustrated in FIG. 4;

FIG. 6 is a perspective view of a wafer peeling unit illustrated in FIG. 1;

FIG. 7 is a fragmentary cross-sectional view of the wafer peeling unit illustrated in FIG. 6;

FIG. 8 is a perspective view of a tray illustrated in FIG. 1;

FIG. 9 is a perspective view of a portion of the wafer manufacturing apparatus illustrated in FIG. 1;

FIG. 10A is a perspective view of a tray stopper in a state where a lifting and lowering plate is positioned in a passing position;

FIG. 10B is a perspective view of the tray stopper in a state where the lifting and lowering plate is positioned in a stopping position;

FIG. 10C is a perspective view of the tray stopper in a state where the lifting and lowering plate is positioned in a spacing position;

FIG. 11A is a cross-sectional view of the tray stopper, etc. in the state illustrated in FIG. 10A;

FIG. 11B is a cross-sectional view of the tray stopper, etc. in the state illustrated in FIG. 10B;

FIG. 11C is a cross-sectional view of the tray stopper, etc. in the state illustrated in FIG. 10C;

FIG. 12A is a perspective view of delivery means in a state where the lifting and lowering plate is in a lifted position;

FIG. 12B is a perspective view of the delivery means in a state where the lifting and lowering plate is in a lowered position;

FIG. 13 is a perspective view of an ingot stocker illustrated in FIG. 1;

FIG. 14 is a perspective view of an ingot transfer unit illustrated in FIG. 1;

FIG. 15 is a perspective view of the ingot stocker illustrated in FIG. 13 and the ingot transfer unit illustrated in FIG. 14 that are combined with each other;

FIG. 16 is a perspective view of a clutch assembly according to another embodiment;

FIG. 17A is a perspective view illustrating a manner in which quality of an ingot is inspected by a quality inspecting unit illustrated in FIG. 1;

FIG. 17B is a side elevational view illustrating the manner in which the quality of the ingot is inspected by the quality inspecting unit illustrated in FIG. 1;

FIG. 17C is a schematic view of an image of an upper surface of the ingot that is captured by image capturing means illustrated in FIG. 17A;

FIG. 18A is a perspective view illustrating a manner in which quality of a wafer is inspected by a quality inspecting unit illustrated in FIG. 1;

FIG. 18B is a side elevational view illustrating the manner in which the quality of the wafer is inspected by the quality inspecting unit illustrated in FIG. 1;

FIG. 18C is a schematic view of an image of an upper surface of the wafer that is captured by image capturing means illustrated in FIG. 18A;

FIG. 19A is a front elevational view of the ingot;

FIG. 19B is a plan view of the ingot;

FIG. 19C is a perspective view of the ingot;

FIG. 20 is a perspective view illustrating a manner in which the ingot is delivered onto a second holding table of the laser applying unit;

FIG. 21A is a perspective view illustrating a manner in which a peel-off layer forming step is carried out;

FIG. 21B is a front elevational view illustrating the manner in which the peel-off layer forming step is carried out;

FIG. 22A is a plan view of the ingot with a peel-off layer formed therein;

FIG. 22B is a cross-sectional view taken along line B-B of FIG. 22A;

FIG. 23A is a perspective view illustrating a manner in which a liquid tank is positioned above a third holding table of the wafer peeling unit;

FIG. 23B is a perspective view illustrating a manner in which the liquid tank has a lower end held in contact with an upper surface of a holding table; and

FIG. 24 is a perspective view illustrating a manner in which a wafer is peeled off from the ingot by the wafer peeling unit.

### DETAILED DESCRIPTION OF THE PREFERRED EMBODIMENTS

A wafer manufacturing apparatus according to a preferred embodiment of the present invention will be described in detail hereinbelow with reference to the drawings.

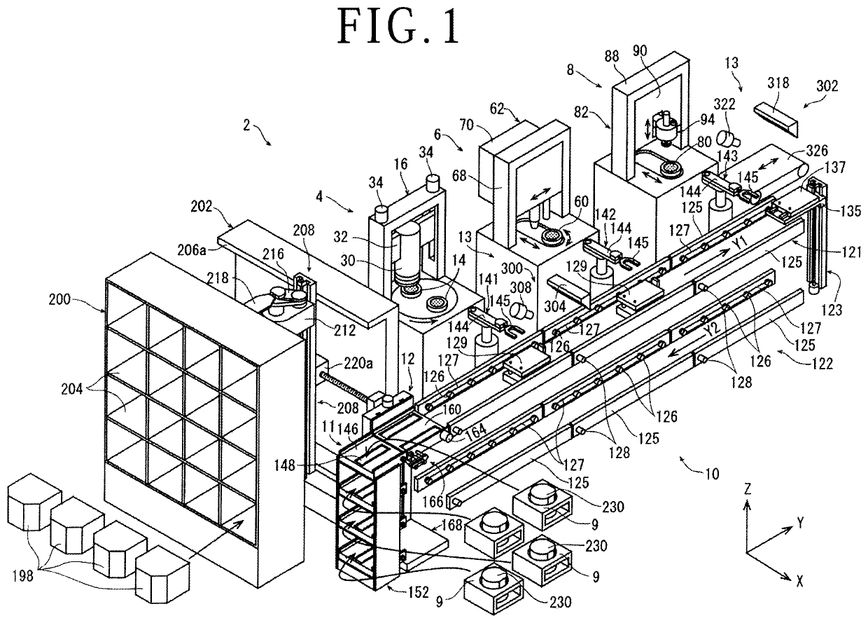

The wafer manufacturing apparatus, denoted by 2 in FIG. 1, includes at least an ingot grinding unit 4, a laser applying unit 6, a wafer peeling unit 8, a plurality of trays 9 each having an ingot support for supporting a semiconductor ingot (hereinafter referred to as an “ingot”) and a wafer support for supporting a wafer peeled off from the ingot, and a belt conveyor unit 10 for delivering ingots supported on trays 9 between the ingot grinding unit 4, the laser applying unit 6, and the wafer peeling unit 8. A quality inspecting unit 13 is disposed adjacent to the belt conveyor unit 10. The wafer manufacturing apparatus 2 according to the present embodiment also includes an ingot stocker 11 for accommodating the ingots supported on the trays 9 and an ingot transfer unit 12 for transferring the ingots supported on the trays 9 accommodated in the ingot stocker 11 to the belt conveyor unit 10.

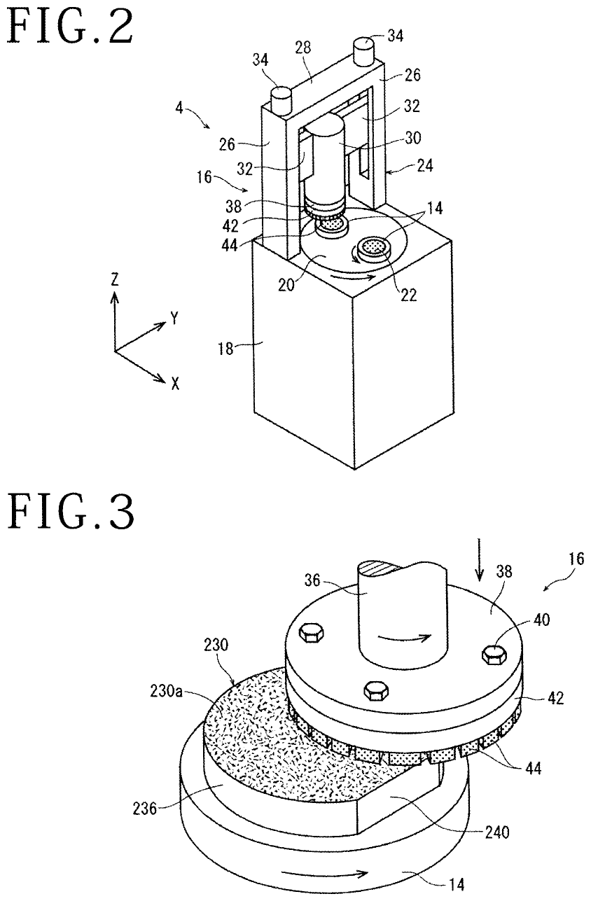

The ingot grinding unit 4 will be described below with reference to FIG. 2. As illustrated in FIG. 2, the ingot grinding unit 4 includes at least a pair of first holding tables 14 of a circular shape each for holding an ingot, and grinding means 16 for grinding an upper surface of one at a time of the ingots held on the first holding tables 14. According to the present embodiment, the ingot grinding unit 4 also includes a base 18 in the shape of a rectangular parallelepiped and a circular turntable 20 rotatably disposed on an upper surface of the base 18. The turntable 20 is rotatable about a vertical axis extending along Z-axis directions passing through a radial center, i.e., a center of rotation, of the turntable 20 by a turntable motor, not illustrated, housed in the base 18. According to the present embodiment, the first holding tables 14 are rotatably mounted on an upper surface of the turntable 20 and disposed in point symmetry across the radial center of the turntable 20. Each of the first holding tables 14 can be positioned alternately in a grinding position, i.e., a position farther from the viewer of FIG. 2, where an ingot is ground by the grinding means 16, and an ingot mounting/dismounting position, i.e., a position closer to the viewer of FIG. 2, where an ingot is mounted on and dismounted from the holding table 14.

Each of the first holding tables 14 is rotatable about a vertical axis extending along the Z-axis directions passing through a radial center of the first holding table 14 by a first holding table motor, not illustrated, mounted on a lower surface of the turntable 20. A porous suction chuck 22 that is connected to suction means, not illustrated, is disposed on an upper surface of the first holding table 14. The first holding table 14 holds an ingot under suction on an upper surface of the suction chuck 22 by a suction force applied to the upper surface of the suction chuck 22 by the suction means. The Z-axis directions refer to upward and downward directions indicated by an arrow Z in FIG. 2. X-axis directions refer to directions indicated by an arrow X in FIG. 2 and extend perpendicularly to the Z-axis directions, and Y-axis directions refer to directions indicated by an arrow Y in FIG. 2 and extend perpendicularly to the X- and Z-axis directions. The X-axis directions and the Y-axis directions jointly define a plane that lies essentially horizontally.

According to the present embodiment, as illustrated in FIG. 2, the grinding means 16 of the ingot grinding unit 4 includes a portal support frame 24 mounted on the upper surface of the base 18. The support frame 24 has a pair of support posts 26 spaced apart from each other in the Y-axis directions and extending upwardly from the upper surface of the base 18 and a beam 28 spanning between respective upper ends of the support posts 26 and extending along the Y-axis directions. A spindle housing 30 is supported on the support posts 26 by a pair of joints 32 and movable in the Z-axis directions, i.e., can be lifted and lowered along the support posts 26. A pair of lifting and lowering motors 34 are mounted on an upper surface of the beam 28 for moving the spindle housing 30 in the Z-axis directions, i.e., lifting and lowering the spindle housing 30 along the support posts 26. Specifically, the lifting and lowering motors 34 have respective output shafts, not illustrated, connected to ends of ball screws, not illustrated, extending along the Z-axis directions in the support posts 26 and operatively threaded through respective nuts, not illustrated, fixed to the joints 32. When the lifting and lowering motors 34 are energized, their output shafts rotate the respective ball screws about their own axes, causing the nuts to convert the rotary motion of the ball screws into linear motion of the joints 32 along the support posts 26, thereby lifting and lowering the spindle housing 30.

A spindle 36 (see FIG. 3) is rotatably supported in the spindle housing 30 for rotation about an axis extending along the Z-axis directions. The spindle 36 can be rotated about the axis extending along the Z-axis directions by a spindle motor, not illustrated, housed in the spindle housing 30. A wheel mount 38 shaped as a circular plate is fixed to a lower end of the spindle 36, and an annular grinding wheel 42 is fixed to a lower surface of the wheel mount 38 by a plurality of bolts 40. An annular array of grindstones 44 that are spaced at angular intervals in circumferential directions thereof is secured to an outer circumferential edge portion of a lower surface of the grinding wheel 42. As illustrated in FIG. 3, a center of rotation of the grinding wheel 42 is displaced from the center of rotation of the first holding table 14 such that, when the first holding table 14 is positioned in the grinding position and the first holding table 14 and the grinding wheel 42 are rotated relatively to each other, the grindstones 44 pass through the center of rotation of the first holding table 14. Therefore, the grinding means 16 can grind the entire upper surface of the ingot held on the first holding table 14 with the grindstones 44 by keeping the grindstones 44 in contact with the upper surface of the ingot held on the first holding table 14 while rotating the first holding table 14 and the grinding wheel 42 relatively to each other. According to the present embodiment, the wafer manufacturing apparatus 2 includes the single ingot grinding unit 4. However, the wafer manufacturing apparatus according to the present invention may include an ingot grinding unit having grindstones for rough grinding and an ingot grinding unit having grindstones for finishing grinding, the ingot grinding units being disposed in tandem.

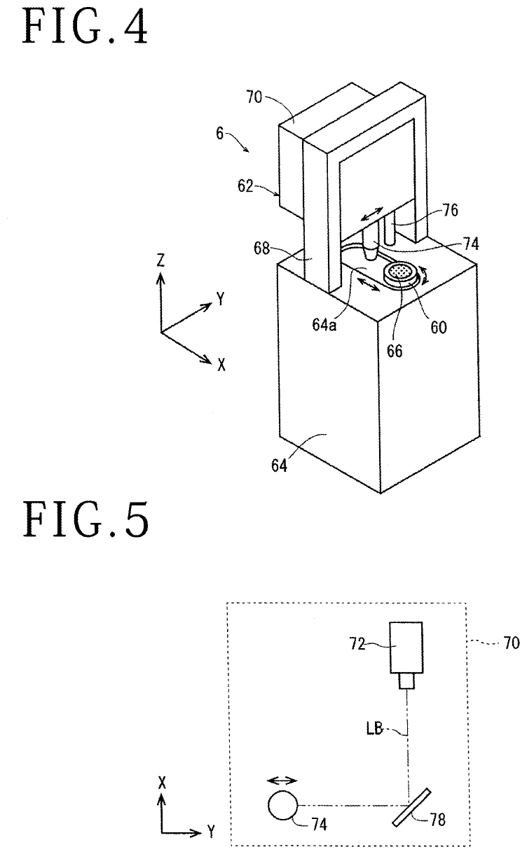

The laser applying unit 6 will be described below with reference to FIGS. 1 and 4. As illustrated in FIG. 1, the laser applying unit 6 that is disposed adjacent to the ingot grinding unit 4 includes at least a second holding table 60 of a circular shape for holding an ingot thereon and laser applying means 62 for applying a laser beam to the ingot to form peel-off layers in the ingot by positioning a focused spot of the laser beam that has a wavelength transmittable through the ingot at a depth in the ingot that corresponds to a thickness of a wafer to be produced from an upper end portion of the ingot held on the second holding table 60.

According to the present embodiment, as illustrated in FIG. 4, the laser applying unit 6 also includes a base 64 in the shape of a rectangular parallelepiped that has a downwardly recessed mounting recess 64a defined in an upper surface thereof and extending along the X-axis directions. The second holding table 60 according to the present embodiment is mounted in the mounting recess 64a in the base 64, and is movable in the X-axis directions and rotatable about an axis extending along the Z-axis directions. The base 64 houses therein X-axis feeding means, not illustrated, for moving the second holding table 60 in the X-axis directions along the mounting recess 64a and a second holding table motor, not illustrated, for rotating the second holding table 60 about the axis extending along the Z-axis directions through a radial center of the second holding table 60. The X-axis feeding means may have, for example, a ball screw coupled to the second holding table 60 and extending along the X-axis directions and a motor for rotating the ball screw about its central axis. The second holding table motor is movable with the second holding table 60 in the X-axis directions by the X-axis feeding means. Therefore, even when the second holding table 60 is moved in the X-axis directions by the X-axis feeding means, the second holding table motor can rotate the second holding table 60. A porous suction chuck 66 that is connected to suction means, not illustrated, is disposed on an upper surface of the second holding table 60. The second holding table 60 holds an ingot under suction on the upper surface of the suction chuck 66 by a suction force applied to the upper surface of the suction chuck 66 by the suction means.

As illustrated in FIG. 4, the laser applying means 62 of the laser applying unit 6 includes a portal support frame 68 mounted on the upper surface of the base 64, a casing 70 supported on and disposed in the support frame 68, a Y-axis movable member, not illustrated, movably mounted on a lower end of the casing 70 for movement in the Y-axis directions, and Y-axis feeding means, not illustrated, for moving the Y-axis movable member in the Y-axis directions. The Y-axis feeding means may have, for example, a ball screw coupled to the Y-axis movable member and extending along the Y-axis directions and a motor for rotating the ball screw about its central axis.

The laser applying means 62 will be described below with reference to FIGS. 4 and 5. The laser applying means 62 includes a laser oscillator 72 (see FIG. 5) housed in the casing 70, a beam condenser 74 (see FIGS. 4 and 5) vertically movably mounted on a lower end of the Y-axis movable member, alignment means 76 (see FIG. 4) mounted on the lower end of the Y-axis movable member at a position spaced from the beam condenser 74 in the Y-axis directions, and focused spot position adjusting means, not illustrated, for lifting or lowering, i.e., vertically moving, the beam condenser 74 to adjust the position in the Z-axis directions of a focused spot of a pulsed laser beam LB that is focused by the beam condenser 74. The laser oscillator 72 oscillates pulsed laser having a wavelength transmittable through the ingot and emits the pulsed laser beam LB to travel in an optical path along the X-axis directions. The beam condenser 74 has a condensing lens, not illustrated, for focusing the pulsed laser beam LB emitted from the laser oscillator 72. The alignment means 76 captures an image of the ingot held on the second holding table 60 and detects an area of the ingot to be processed by the pulsed laser beam LB on the basis of the captured image. The focused spot position adjusting means may have, for example, a ball screw coupled to the beam condenser 74 and extending along the Z-axis directions and a motor for rotating the ball screw about its central axis.

As illustrated in FIG. 5, the casing 70 houses therein a first mirror 78 spaced in the X-axis directions from the laser oscillator 72, for reflecting the pulsed laser beam LB emitted from the laser oscillator 72 along the X-axis directions to travel in an optical path along the Y-axis directions, and a second mirror, not illustrated, spaced in the Y-axis directions from the first mirror 78 and disposed above the beam condenser 74, for reflecting the pulsed laser beam LB that has traveled in the optical path along the Y-axis directions from the first mirror 78 to travel in an optical path along the Z-axis directions toward the beam condenser 74.

The second mirror is mounted on the Y-axis movable member. When the Y-axis movable member is moved by the Y-axis feeding means, the second mirror is moved in the Y-axis directions in unison with the beam condenser 74 and the alignment means 76. The pulsed laser beam LB emitted from the laser oscillator 72 to travel in the optical path along the X-axis directions is reflected by the first mirror 78 to travel in the optical path along the Y-axis directions toward the second mirror. The pulsed laser beam LB that has traveled in the optical path along the Y-axis directions from the first mirror 78 is reflected by the second mirror to travel in the optical path along the Z-axis directions toward the beam condenser 74. The pulsed laser beam LB is then focused by the condensing lens of the beam condenser 74 and applied to the ingot held on the second holding table 60. When the beam condenser 74 is moved in the Y-axis directions by the Y-axis movable member moved by the Y-axis feeing means or when the beam condenser 74 is lifted or lowered by the focused spot position adjusting means, the pulsed laser beam LB emitted from the laser oscillator 72 along the X-axis directions is also reflected by the first mirror 78 to travel along the Y-axis directions toward the second mirror and then reflected by the second mirror to travel along the Z-axis directions toward the beam condenser 74.

The laser applying means 62 operates in the following manner. The alignment means 76 captures an image of the ingot held on the second holding table 60 and detects an area of the ingot to be processed by the pulsed laser beam LB on the basis of the captured image. The focused spot position adjusting means lifts or lowers the beam condenser 74 to position the focused spot of the pulsed laser beam LB whose wavelength is transmittable through the ingot at a depth in the ingot that corresponds to the thickness of a wafer to be produced from an upper end portion of the ingot held on the second holding table 60. Then, while the Y-axis feeding means is moving the beam condenser 74 in the Y-axis directions, the laser applying means 62 applies the pulsed laser beam LB to the ingot held on the second holding table 60, forming peel-off layers of reduced mechanical strength in the ingot. When the laser applying means 62 applies the pulsed laser beam LB to the ingot held on the second holding table 60, the X-axis feeding means may move the second holding table 60 along the X-axis directions.

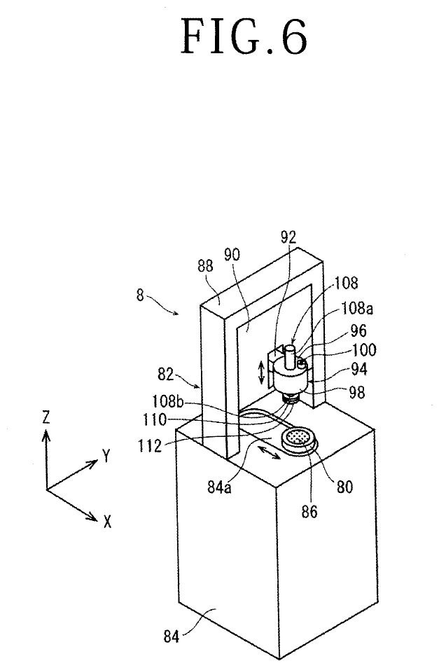

The wafer peeling unit 8 will be described below with reference to FIGS. 1 and 6. As illustrated in FIG. 1, the wafer peeling unit 8 that is disposed adjacent to the laser applying unit 6 includes at least a third holding table 80 of a circular shape for holding an ingot thereon and wafer peeling means 82 for holding the upper surface of the ingot held on the third holding table 80 and peeling off a wafer from the ingot at the peel-off layers therein.

According to the present embodiment, as illustrated in FIG. 6, the wafer peeling unit 8 also includes a base 84 in the shape of a rectangular parallelepiped that has a downwardly recessed mounting recess 84a defined in an upper surface thereof and extending along the X-axis directions. The third holding table 80 according to the present embodiment is mounted in the mounting recess 84a in the base 84, and is movable in the X-axis directions. The base 84 houses therein X-axis feeding means, not illustrated, for moving the third holding table 80 in the X-axis directions along the mounting recess 84a. The X-axis feeding means may have, for example, a ball screw coupled to the third holding table 80 and extending along the X-axis directions and a motor for rotating the ball screw about its central axis. A porous suction chuck 86 that is connected to suction means, not illustrated, is disposed on an upper surface of the third holding table 80. The third holding table 80 holds an ingot under suction on the upper surface of the suction chuck 86 by a suction force applied to the upper surface of the suction chuck 86 by the suction means.

As illustrated in FIG. 6, the wafer peeling means 82 of the wafer peeling unit 8 includes a portal support frame 88 mounted on the upper surface of the base 84, a casing 90 supported on and disposed in the support frame 88, an arm 92 having a proximal end vertically movably supported on the casing 90 and extending along the X-axis directions from the proximal end, and arm moving means, not illustrated, for lifting and lowering the arm 92. The arm moving means may have, for example, a ball screw coupled to the proximal end of the arm 92 and extending along the Z-axis directions and a motor for rotating the ball screw about its central axis.

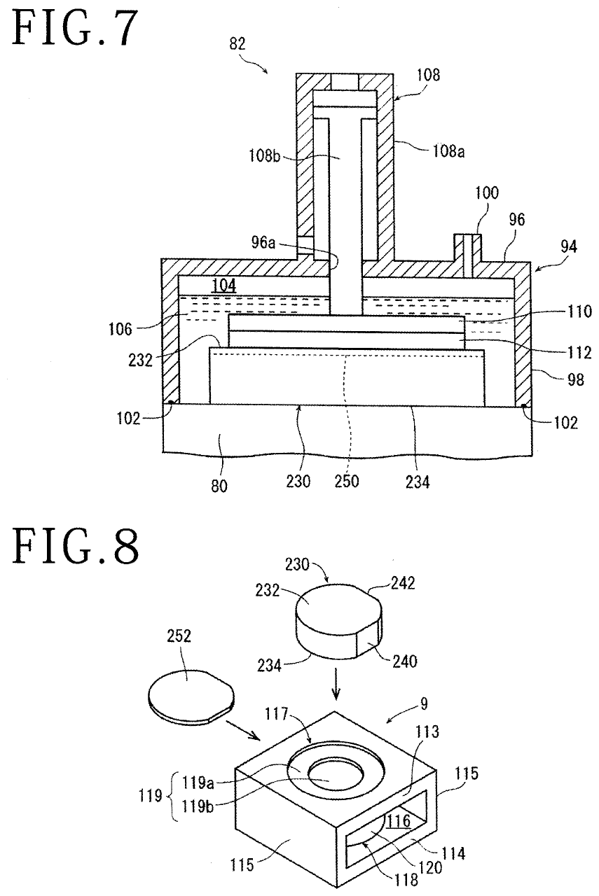

The wafer peeling means 82 will be described below with reference to FIGS. 6 and 7. As illustrated in FIGS. 6 and 7, the wafer peeling means 82 also includes a liquid tank 94 fixed to a distal end of the arm 92 for accommodating therein a liquid in cooperation with the third holding table 80 at the time a wafer is peeled off from the ingot. The liquid tank 94 has an upper wall 96 of a circular shape and a hollow cylindrical skirt wall 98 hanging from a peripheral edge of the upper wall 96, and has an open lower end. The skirt wall 98 has an outside diameter smaller than a diameter of the third holding table 80. When the arm 92 is lowered, the skirt wall 98 has a lower end brought into contact with the upper surface of the third holding table 80. A tubular liquid supply member 100 is joined to the upper wall 96, providing fluid communication between outer and inner areas of the liquid tank 94, and is connected to liquid supply means, not illustrated. As illustrated in FIG. 7, an annular packing 102 is joined to the lower end of the skirt wall 98. When the arm moving means lowers the arm 92 to bring the lower end of the skirt wall 98 into contact with the upper surface of the third holding table 80, the upper surface of the third holding table 80 and an inner surface of the liquid tank 94 jointly define a liquid accommodating space 104 therebetween. The liquid supply means supplies and introduces a liquid 106 through the liquid supply member 100 into the liquid accommodating space 104. The liquid 106 is prevented from leaking out of the liquid accommodating space 104 by the packing 102.

As illustrated in FIG. 7, an air cylinder 108 is mounted on the upper wall 96 of the liquid tank 94 and has a cylinder tube 108a extending upwardly from an upper surface of the upper wall 96. The air cylinder 108 includes a piston rod 108b housed therein that has a lower end portion extending through a through opening 96a defined in the upper wall 96 and protruding downwardly from the upper wall 96. The piston rod 108b has a lower end fixed to an ultrasonic vibration generator 110, which may be made of piezoelectric ceramic or the like, with a suction member 112 fixed to a lower surface thereof. The suction member 112 has a plurality of suction holes, not illustrated, defined in a lower surface thereof and connected to suction means, not illustrated. When the suction means applies a suction force to the lower surface of the suction member 112 through the suction holes, the suction member 112 holds an ingot under suction on the lower surface thereof.

The wafer peeling means 82 operates in the following manner. The arm moving means lowers the arm 92 until the lower end of the skirt wall 98 is brought into intimate contact with the upper surface of the third holding table 80 that holds thereon an ingot with peel-off layers formed therein. The piston rod 108b of the air cylinder 108 is lowered to bring the suction member 112 into contact with the upper surface of the ingot held on the third holding table 80. The suction means applies a suction force to the lower surface of the suction member 112 through the suction holes, holding the ingot under suction on the lower surface of the suction member 112. After the liquid 106 has been introduced into the liquid accommodating space 104, the ultrasonic vibration generator 110 is actuated to apply ultrasonic vibrations to the ingot, lowering the mechanical strength of the peel-off layers in the ingot. In the wafer peeling means 82, while the upper surface of the ingot is being attracted under suction by the suction member 112, the air cylinder 108 can lift the piston rod 108b and hence the suction member 112, peeling off a disk-shaped ingot portion as a wafer from the ingot at the peel-off layers of the lowered mechanical strength that act as severance initiating points.

The trays 9 will be described below with reference to FIG. 8. Since the trays 9 are structurally identical to each other, one of the trays 9 will be described below. According to the present embodiment, the tray 9 is constructed as a housing including a rectangular upper wall 113, a rectangular lower wall 114 disposed below and spaced downwardly from the upper wall 113, a pair of side walls 115 disposed between and joining the upper and lower walls 113 and 114 to each other, and a cavity 116 defined between the upper and lower walls 113 and 114 and extending between the side walls 115 all the way across the upper and lower walls 113 and 114. The tray 9 also includes an ingot support portion 117 disposed on an upper surface of the upper wall 113 for supporting an ingot thereon and a wafer support portion 118 on an upper surface of the lower wall 114 for supporting a wafer peeled off from the ingot.

The ingot support portion 117 according to the present embodiment includes recesses 119 corresponding to ingots of two or more different sizes. The recesses 119 include an annular larger-diameter recess 119a downwardly recessed from the upper surface of the upper wall 113 and a circular smaller-diameter recess 119b smaller in diameter than the larger-diameter recess 119a and downwardly recessed from a bottom of the larger-diameter recess 119a. The larger-diameter recess 119a and the smaller-diameter recess 119b are concentric with each other. The tray 9 can support an ingot having a relatively large diameter of 6 inches, for example, in the larger-diameter recess 119a or an ingot having a relatively small diameter of 5 inches, for example, in the smaller-diameter recess 119b.

The wafer support portion 118 includes recesses 120 corresponding to wafers of two or more different sizes. Although not illustrated in detail, as is the case with the recesses 119 of the ingot support portion 117, the recesses 120 may include an annular larger-diameter recess downwardly recessed from the upper surface of the lower wall 114 and a circular smaller-diameter recess smaller in diameter than the larger-diameter recess and downwardly recessed from a bottom of the larger-diameter recess. The larger-diameter recess and the smaller-diameter recess may be concentric with each other. The tray 9 can support a wafer having a relatively large diameter of 6 inches, for example, in the larger-diameter recess of the wafer support portion 118 or a wafer having a relatively small diameter of 5 inches, for example, in the smaller-diameter recess of the wafer support portion 118. Alternatively, the tray 9 may have a wafer support portion on the upper surface of the upper wall 113 and an ingot support portion on the upper surface of the lower wall 114.

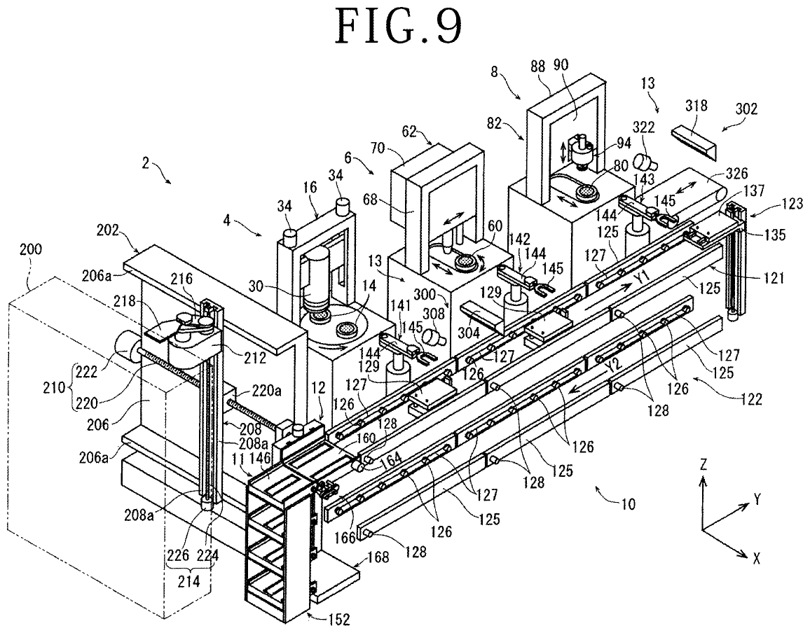

The belt conveyor unit 10 will be described below with reference to FIG. 9. The belt conveyor unit 10 that is disposed along the ingot grinding unit 4, the laser applying unit 6, and the wafer peeling unit 8 includes at least a plurality of (three in the present embodiment) forward belt conveyors 121 for delivering trays 9 in a Y1 direction indicated by an arrow Y1 in FIG. 9 as one of the Y-axis directions, a plurality of (three in the present embodiment) return belt conveyors 122 for delivering trays 9 in a Y2 direction indicated by an arrow Y2 in FIG. 9 as the other of the Y-axis directions, which is opposite the Y1 direction, and delivery means 123 for delivering trays 9 from an end point of the forward belt conveyors 121 to a start point of the return belt conveyors 122.

Each of the forward belt conveyors 121 includes a pair of support walls 125 spaced from each other in the X-axis directions and extending along the Y-axis directions, a plurality of rollers 126 rotatably mounted on an inner surface of each of the support walls 125 at spaced intervals along the Y-axis directions, a pair of endless belts 127 trained around the rollers 126 for carrying trays 9 thereon, and a pair of motors 128 mounted on outer surfaces of the support walls 125 for rotating the rollers 126. According to the present embodiment, the three forward belt conveyors 121 are arrayed along the Y-axis directions. However, the number of the forward belt conveyors 121 and lengths of the support walls 125 along the Y-axis directions may be changed to change a length of the path along which the trays 9 are delivered. When the endless belts 127 are actuated by the rollers 126 rotated by the motors 128, the trays 9 carried on the endless belts 127 are delivered in the Y1 direction.

According to the present embodiment, as illustrated in FIG. 9, the return belt conveyors 122 that are disposed underneath the forward belt conveyors 121 may essentially be identical in structure to the forward belt conveyors 121. Therefore, the components of the return belt conveyors 122 are denoted by identical reference symbols to those of the components of the forward belt conveyors 121. When the return belt conveyors 122 operate, the endless belts 127 are actuated by the rollers 126 rotated by the motors 128 in a direction opposite the direction in which the endless belts 127 of the forward belt conveyors 121 are actuated, delivering the trays 9 carried on the endless belts 127 in the Y2 direction. The return belt conveyors 122 may be disposed above the forward belt conveyors 121. While the wafer manufacturing apparatus 2 is in operation, both the forward belt conveyors 121 and the return belt conveyors 122 should preferably be actuated at all the time.

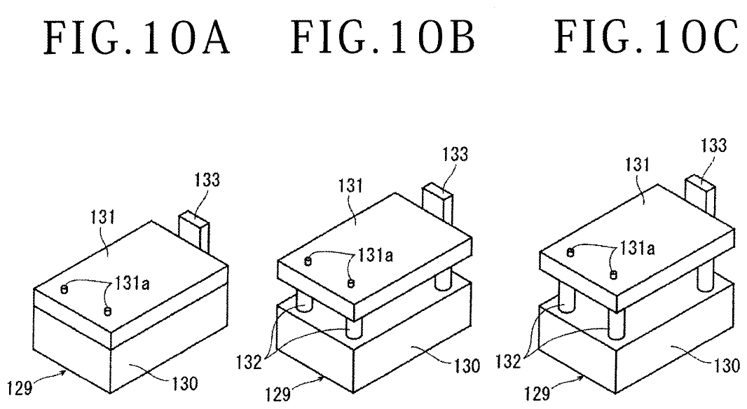

As illustrated in FIG. 9, tray stoppers 129 for stopping the trays 9 delivered by the forward belt conveyors 121 are disposed at a position on the forward belt conveyors 121 that faces the ingot grinding unit 4 and a position on the forward belt conveyors 121 that faces the laser applying unit 6. According to the present embodiment, as illustrated in FIGS. 10A through 10C, each of the tray stoppers 129 includes a base plate 130 fixed in position by a suitable bracket, not illustrated, a lifting and lowering plate 131 vertically movably supported on an upper surface of the base plate 130, cylinder means 132 for vertically moving the lifting and lowering plate 131, and a stopper piece 133 fixed to an end of the lifting and lowering plate 131 that is located downstream in the Y1 direction.

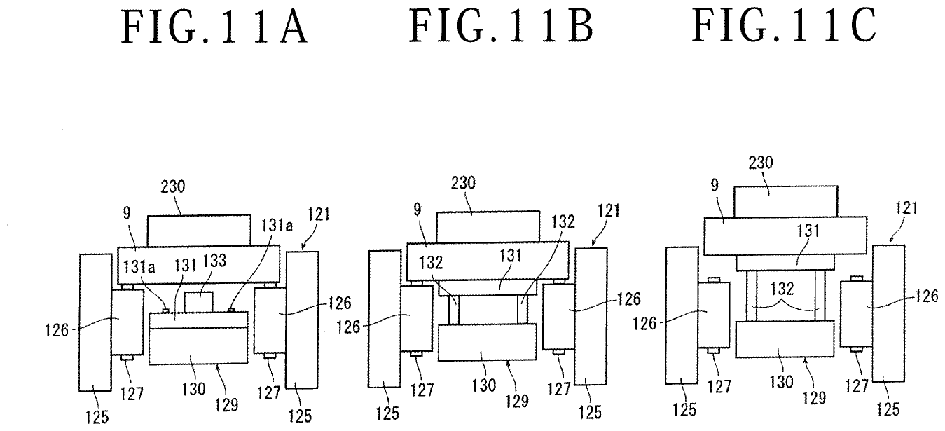

As illustrated in FIGS. 10A through 10C, the lifting and lowering plate 131 has a pair of engaging pins 131a disposed on an upper surface thereof for engaging in a pair of respective engagement recesses, not illustrated, defined in a lower surface of the lower wall 114 of each of the trays 9. As illustrated in FIGS. 10A through 10C and FIGS. 11A through 11C, the cylinder means 132, which may be actuated pneumatically or electrically, positions the lifting and lowering plate 131 selectively in a passing position, e.g., the position illustrated in FIGS. 10A and 11A, where the stopper piece 133 has its upper end positioned below a lower end of a tray 9 delivered by the forward belt conveyors 121, a stopping position, e.g., the position illustrated in FIGS. 10B and 11B, where the stopper piece 133 contacts the tray 9 delivered by the forward belt conveyors 121, and a spacing position, e.g., the position illustrated in FIGS. 10C and 11C, where the tray 9 is spaced from the endless belts 127.

When the tray stopper 129 positions the lifting and lowering plate 131 in the passing position, the tray stopper 129 allows the tray 9 to pass thereover (see FIG. 11A). When the tray stopper 129 positions the lifting and lowering plate 131 in the stopping position above the passing position, the tray stopper 129 stops the tray 9 delivered by the forward belt conveyors 121 (see FIG. 11B). Further, When the tray stopper 129 positions the lifting and lowering plate 131 in the spacing position above the stopping position, the tray stopper 129 spaces the stopped tray 9 upwardly from the endless belts 127, preventing the lower surface of the tray 9 and upper surfaces of the endless belts 127 from slidingly contacting each other and hence preventing a load imposed on the motors 128 of the forward belt conveyors 121 from increasing (see FIG. 11C). In the stopping position and the spacing position, the engaging pins 131a of the lifting and lowering plate 131 engage in the respective engagement recesses of the tray 9, preventing the tray 9 from being positionally shifted with respect to the lifting and lowering plate 131.

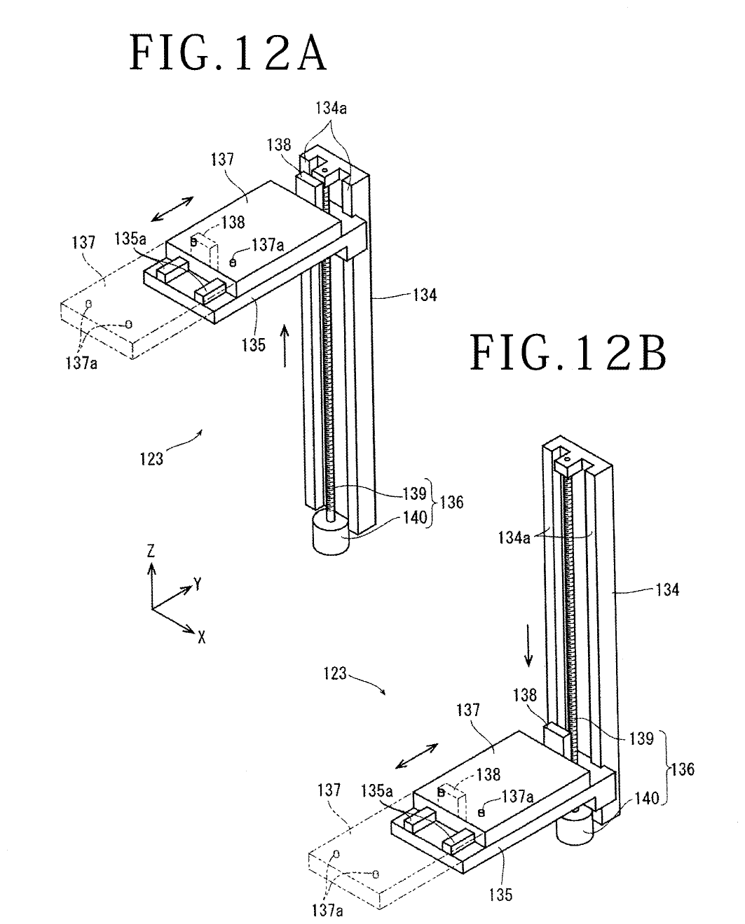

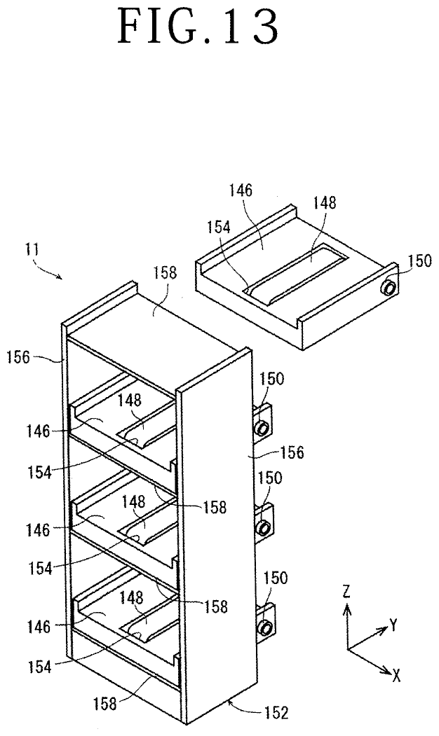

The delivery means 123 will be described below with reference to FIGS. 9, 12A, and 12B. The delivery means 123 that is disposed adjacent to the end point of the forward belt conveyors 121 and the start point of the return belt conveyors 122 includes a support wall 134 extending along the Z-axis directions, a lifting and lowering plate 135 vertically movably supported on the support wall 134 for moving along the Z-axis directions, lifting and lowering means 136 for lifting and lowering the lifting and lowering plate 135 along the Z-axis directions, a Y-axis movable plate 137 movably supported on an upper surface of the lifting and lowering plate 135 for movement along the Y-axis directions, Y-axis feeding means, not illustrated, for moving the Y-axis movable plate 137 along the Y-axis directions, and a stopper piece 138 fixed to an end of the Y-axis movable plate 137 that is located downstream in the Y1 direction.

The lifting and lowering means 136 has a ball screw 139 coupled to the lifting and lowering plate 135 and extending along the Z-axis directions and a motor 140 for rotating the ball screw 139 about its central axis. The lifting and lowering means 136 lifts and lowers the lifting and lowering plate 135 along a pair of guide rails 134a on the support wall 134 in the Z-axis directions between a lifted position illustrated in FIG. 12A and a lowered position illustrated in FIG. 12B and stops the lifting and lowering plate 135 at any position between the lifted position and the lowered position. The Y-axis movable plate 137 has a pair of engaging pins 137a disposed on an upper surface thereof for engagement in the respective engagement recesses of a tray 9. The Y-axis feeding means, which includes an air cylinder or an electric cylinder, for example, moves the Y-axis movable plate 137 along a pair of guide rails 135a on the lifting and lowering plate 135 in the Y-axis directions between an advanced position indicated by two-dot-and-dash lines in FIGS. 12A and 12B and a retracted position indicated by solid lines in FIGS. 12A and 12B.

The delivery means 123 operates in the following manner. The upper surface of the Y-axis movable plate 137 is positioned slightly below the upper surfaces of the endless belts 127 of the forward belt conveyors 121, and the Y-axis movable plate 137 is positioned in the advanced position. As a result, the stopper piece 138 contacts a tray 9 being delivered by the most downstream forward belt conveyor 121, stopping the tray 9 at the end point of the forward belt conveyors 121 that also represents a position facing the wafer peeling unit 8 according to the present embodiment. With the tray 9 stopped at the end point of the forward belt conveyors 121, the lifting and lowering plate 135 is lifted to space the lower surface of the tray 9 from the upper surfaces of the endless belts 127 and place the tray 9 on the upper surface of the Y-axis movable plate 137. When the tray 9 is placed on the Y-axis movable plate 137, the engaging pins 137a engage in the respective engagement recesses of the tray 9, preventing the tray 9 from being positionally shifted on the Y-axis movable plate 137. Moreover, the Y-axis movable plate 137 with the tray 9 placed thereon is positioned in the retracted position, and the lifting and lowering plate 135 is lowered until the upper surface of the Y-axis movable plate 137 is positioned slightly above the upper surfaces of the endless belts 127 of the return belt conveyors 122. Then, the Y-axis movable plate 137 is positioned in the advanced position, and the lifting and lowering plate 135 is slightly lowered, thereby transferring the tray 9 from the Y-axis movable plate 137 onto the endless belts 127 of the most upstream return belt conveyor 122. In this manner, the delivery means 123 delivers the tray 9 from the end point of the forward belt conveyors 121 to the start point of the return belt conveyors 122.

According to the present embodiment, as illustrated in FIG. 9, the belt conveyor unit 10 further includes first transferring means 141 for transferring an ingot between a tray 9 stopped by the tray stopper 129 closer to the start point of the forward belt conveyors 121 and the ingot grinding unit 4, second transferring means 142 for transferring an ingot between a tray 9 stopped by the tray stopper 129 closer to the end point of the forward belt conveyors 121 and the laser applying unit 6, and third transferring means 143 for transferring an ingot between a tray 9 stopped by the delivery means 123 and the wafer peeling unit 8 and transferring a wafer peeled off from the ingot from the wafer peeling unit 8 to the tray 9.

The second transferring means 142 and the third transferring means 143 may be structurally identical to the first transferring means 141. Therefore, structural details of the first transferring means 141 will be described below, and those of the second transferring means 142 and the third transferring means 143 will be omitted from description. The first transferring means 141 includes an articulated arm 144, an actuator, not illustrated, for actuating the articulated arm 144, and a U-shaped suction member 145 mounted on a distal end of the articulated arm 144. The actuator, which may be actuated pneumatically or electrically, actuates the articulated arm 144 to position the suction member 145 in any positions in the X-axis directions, the Y-axis directions, and the Z-axis directions and also to vertically reverse the suction member 145, i.e., to turn the suction member 145 upside down. The suction member 145 has a plurality of suction holes, not illustrated, defined in one surface thereof that are connected to suction means, not illustrated. When the suction means generates and applies a suction force to the suction holes in the suction member 145, the first transferring means 141 holds an ingot under suction on the suction member 145. Moreover, the actuator of the first transferring means 141 actuates the articulated arm 144 to transfer the ingot held under suction on the suction member 145 between the tray 9 stopped by the tray stopper 129 and the ingot grinding unit 4. Each of the suction members 145 of the first and second transferring means 141 and 142 may not be U-shaped, but may be shaped as a circular plate.

The ingot stocker 11 will be described below with reference to FIG. 13. According to the present embodiment, the ingot stocker 11 includes at least a plurality of rest tables 146 each for placing thereon a tray 9 with an ingot supported thereon, a plurality of first endless belts 148 for unloading trays 9 placed on the respective rest tables 146 and supporting respective ingots thereon, a plurality of drive force transmitters 150 coupled to the respective first endless belts 148 for transmitting drive forces to the first endless belts 148, and a rack 152 in which the rest tables 146 are disposed in a vertical array.

As illustrated in FIG. 13, each of the rest tables 146 that are of a rectangular shape has an oblong rectangular opening 154 defined in an upper surface thereof and extending along the Y-axis directions. A plurality of rollers, not illustrated, are rotatably mounted in each of the rest tables 146. One of the first endless belts 148 is trained around the rollers in each of the rest tables 146 and has its upper surface exposed through the oblong rectangular opening 154. Each of the drive force transmitters 150 that are of a hollow cylindrical shape extending along the X-axis directions is rotatably mounted on one of the rest tables 146. The drive force transmitter 150 has an end protruding from an outer side surface of an end of the rest table 146 in one of the Y-axis directions and another end coupled to one of the rollers around which the first endless belt 148 is trained. According to the present embodiment, the rack 152 includes a pair of side plates 156 spaced apart along the X-axis directions and four shelf boards 158 disposed between the side plates 156 and spaced apart along the Z-axis directions. The rest tables 146 are disposed on the respective shelf boards 158. The ingot stocker 11 operates in the following manner. When one of the drive force transmitters 150 is actuated, it rotates the roller coupled thereto to actuate the corresponding first endless belt 148 to unload the tray 9 placed on the upper surface of the rest table 146 out of the ingot stocker 11 in one of the Y-axis directions. One of the rollers in the rest table 146 may be a hollow cylindrical member doubling as the drive force transmitter 150.

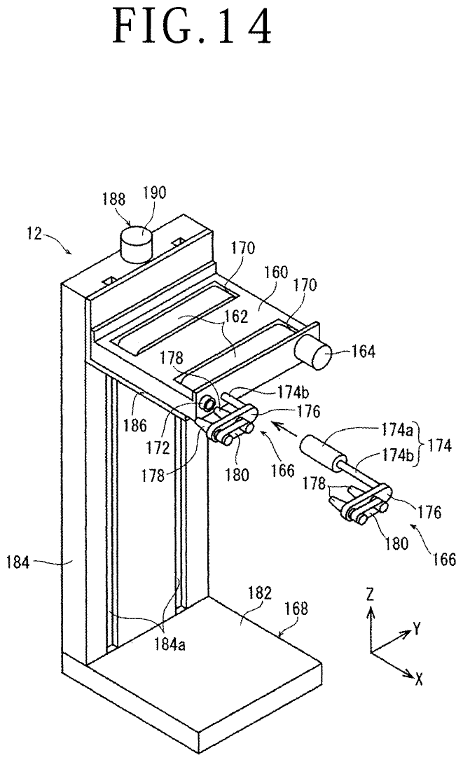

The ingot transfer unit 12 will be described below with reference to FIGS. 1 and 14. As illustrated in FIG. 1, the ingot transfer unit 12 is disposed between the belt conveyor unit 10 and the ingot stocker 11. As illustrated in FIG. 14, the ingot transfer unit 12 according to the present embodiment includes at least a receiving table 160 for receiving a tray 9 with an ingot supported thereon from one of the rest tables 146 in the ingot stocker 11, a pair of second endless belts 162 incorporated in the receiving table 160 for transferring the tray 9 with the ingot supported thereon from the receiving table 160 to the belt conveyor unit 10, a motor 164 mounted on the receiving table 160 for actuating the second endless belts 162, a clutch assembly 166 coupled to the second endless belts 162 for transmitting a drive force from the second endless belts 162 to the drive force transmitter 150 of the rest table 146 in the ingot stocker 11, and an elevator 168 for positioning the receiving table 160 into alignment with one at a time of the vertically arrayed rest tables 146 in the ingot stocker 11.

As illustrated in FIG. 14, the receiving table 160 that is of a rectangular shape has a pair of oblong rectangular openings 170 defined in an upper surface thereof that are spaced apart from each other in the X-axis directions and extending along the Y-axis directions. A plurality of rollers, not illustrated, are rotatably mounted in the receiving table 160. The pair of second endless belts 162 are trained around the rollers in the receiving table 160 and has their upper surfaces exposed through the oblong rectangular openings 170. A drive force transmitter 172 shaped as a hollow cylinder extending along the X-axis directions is rotatably mounted on an end of the receiving table 160 in one of the Y-axis directions. The drive force transmitter 172 has an end protruding from an outer side surface of the end of the receiving table 160 and another end coupled to one of the rollers around which the second endless belts 162 are trained. The motor 164 is mounted on the outer side surface of the other end of the receiving table 160 in the other of the Y-axis directions. The motor 164 has its rotatable output shaft, not illustrated, coupled to one of the rollers around which the second endless belts 162 are trained. One of the rollers in the receiving table 160 may be a hollow cylindrical member doubling as the drive force transmitter 172.

The ingot transfer unit 12 will further be described below with reference to FIG. 14. The clutch assembly 166 includes an air cylinder 174 having a cylinder tube 174a fixed to the receiving table 160 and a piston rod 174b telescopically mounted in the cylinder tube 174a for movement in the X-axis directions, a bracket 176 fixed to a distal end of the piston rod 174b of the air cylinder 174, a pair of tapered pins 178 spaced apart from each other along the Y-axis directions and rotatably mounted on the bracket 176, and an endless transmission belt 180 trained around the tapered pins 178. The elevator 168 includes a base plate 182, a support plate 184 extending upwardly in one of the Z-axis directions from an end of the base plate 182 in one of the X-axis directions, a lifting and lowering plate 186 vertically movably supported on the support plate 184, and lifting and lowering means 188 for lifting and lowering the lifting and lowering plate 186. The receiving table 160 is disposed on an upper surface of the lifting and lowering plate 186. The lifting and lowering means 188 has a ball screw, not illustrated, coupled to the lifting and lowering plate 186 and extending along the Z-axis directions and a motor 190 for rotating the ball screw about its central axis. The lifting and lowering means 188 can lift and lower the lifting and lowering plate 186 along a pair of guide rails 184a in the support plate 184 in the Z-axis directions and stop the lifting and lowering plate 186 at any position on the support plate 184.

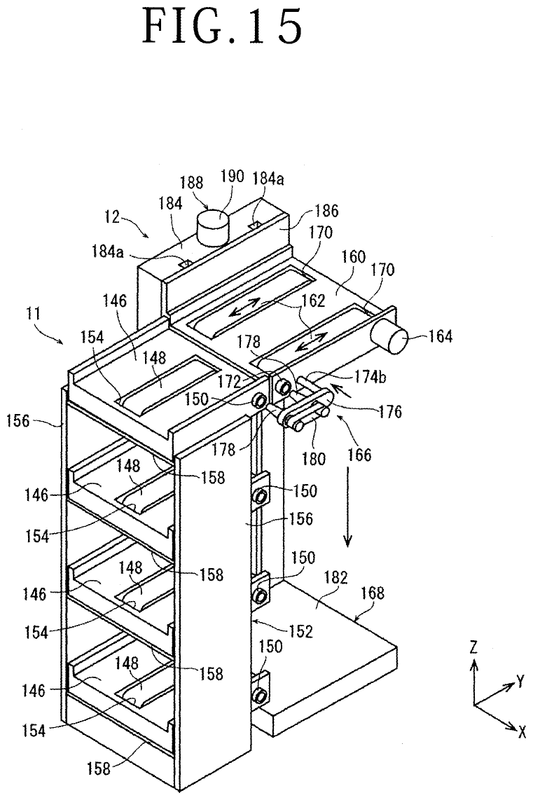

Operation of the ingot transfer unit 12 will be described below with reference to FIG. 15. The lifting and lowering plate 186 of the elevator 168 is lifted or lowered by the motor 190 and then stopped at a position where the upper surface of one of the rest tables 146 of the ingot stocker 11 and the upper surface of the receiving table 160 lie flush with each other. Thereafter, the piston rod 174b of the air cylinder 174 of the clutch assembly 166 is moved from an extended position illustrated in FIG. 15 to a retracted position. One of the tapered pins 178 of the clutch assembly 166 is now inserted into the drive force transmitter 150 of the ingot stocker 11 and rotatably coupled therewith, and the other of the tapered pins 178 is inserted into the drive force transmitter 172 of the ingot transfer unit 12 and rotatably coupled therewith. Then, when the motor 164 is energized, it actuates the second endless belts 162 to rotate the drive force transmitter 172 of the ingot transfer unit 12, the tapered pins 178 with the endless transmission belt 180, and the drive force transmitter 150 of the ingot stocker 11, thereby moving the first endless belt 148 of the ingot stocker 11. The tray 9 placed on the upper surface of the rest table 146 of the ingot stocker 11 is unloaded out of the rack 152 in one of the Y-axis directions by the first endless belt 148 and transferred onto the receiving table 160 of the ingot transfer unit 12.

Moreover, after the tray 9 has been received on the receiving table 160, the motor 164 is de-energized and the piston rod 174b of the air cylinder 174 of the clutch assembly 166 is moved from the retracted position to the extended position, thereby uncoupling the one of the tapered pins 178 from the drive force transmitter 150 of the ingot stocker 11 and uncoupling the other of the tapered pins 178 from the drive force transmitter 172 of the ingot transfer unit 12. The lifting and lowering plate 186 is lifted or lowered by the motor 190 and then stopped at a position where the upper surface of the receiving table 160 with the tray 9 placed thereon and the upper surfaces of the endless belts 127 of the forward belt conveyors 121 of the belt conveyor unit 10 lie flush with each other. Thereafter, the motor 164 is energized to actuate the second endless belts 162, transferring the tray 9 placed on the receiving table 160 onto the most upstream forward belt conveyor 121 of the belt conveyor unit 10. In this manner, the ingot transfer unit 12 transfers the ingots supported on the trays 9 housed in the ingot stocker 11 to the belt conveyor unit 10.

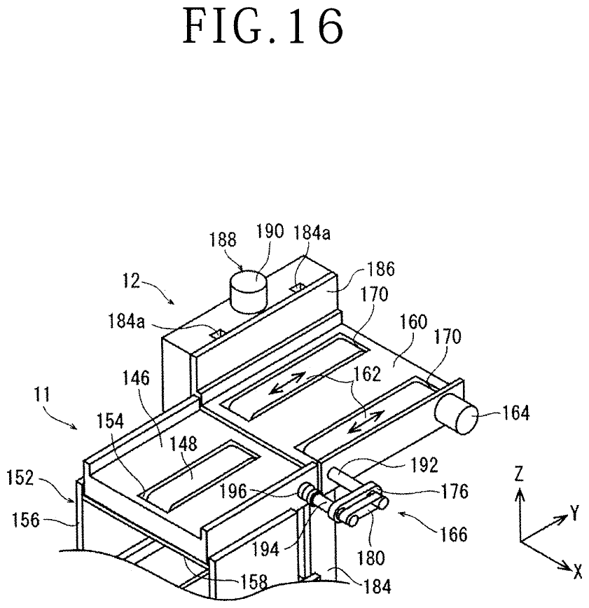

The drive force transmitter 150 of the ingot stocker 11 and the drive force transmitter 172 and the clutch assembly 166 of the ingot transfer unit 12 are not limited to the illustrated structural details according to the above embodiment, but may have structural details according to another embodiment illustrated in FIG. 16. According to the other embodiment illustrated in FIG. 16, the tapered pins 178 of the clutch assembly 166 illustrated in FIG. 15 are replaced with a rotational shaft 192 coupled to the one of the rollers around which the second endless belts 162 are trained in the receiving table 160 and a drive magnet member 194. The rotational shaft 192 and the drive magnet member 194 are rotatably mounted on the bracket 176. A driven magnet member 196 acting as a drive force transmitter is coupled to the one of the rollers around which the first endless belt 148 is trained in the rest table 146. Other details of the embodiment illustrated in FIG. 16 are similar to those of the embodiment illustrated in FIG. 15.

According to the other embodiment illustrated in FIG. 16, after the lifting and lowering plate 186 has been moved to and stopped at the position where the upper surface of the rest table 146 of the ingot stocker 11 and the upper surface of the receiving table 160 lie flush with each other, the rotation of the output shaft of the motor 164 is transmitted to the first endless belt 148 of the rest table 146 through a magnet coupling that includes the drive magnet member 194 and the driven magnet member 196. The magnet coupling may be a noncontact magnet coupling where there is a gap between the drive magnet member 194 and the driven magnet member 196. According to the other embodiment illustrated in FIG. 16, such a noncontact magnet coupling dispenses with the air cylinder 174 for moving the bracket 176 in the X-axis directions as illustrated in FIG. 14.

The wafer manufacturing apparatus 2 according to the present embodiment will further be described below with reference to FIGS. 1 and 9. The wafer manufacturing apparatus 2 according to the present embodiment also includes a cassette stocker 200 for housing therein a plurality of cassettes 198 each containing peeled-off wafers and storing means 202 for storing a wafer supported on the wafer support portion 118 of a tray 9 into a cassette 198 housed in the cassette stocker 200.

As illustrated in FIG. 1, the cassette stocker 200 has a total of 16 cassette housings 204 arranged in four columns in the X-axis directions and four tiers in the Z-axis directions. Each of the cassette housings 204 houses therein a cassette 198 that accommodates therein wafers peeled off from an ingot by the wafer peeling unit 8. The cassette 198 is capable of accommodating a plurality of, e.g., 25, wafers at vertically spaced intervals. The cassette housings 204 extend through the cassette stocker 200 along the Y-axis directions, i.e., have both ends open in the Y-axis directions. Cassettes 198 can be put into the respective cassette housings 204 through their open ends that face the viewer of FIG. 1, and wafers can be stored into the cassettes 198 in the cassette housings 204 through their open ends that face away from the viewer of FIG. 1.

As illustrated in FIG. 9, the storing means 202 is disposed adjacent to the ingot transfer unit 12 and the cassette stocker 200. The storing means 202 includes a support wall 206, an X-axis movable member 208 movably supported on the support wall 206 for movement along the X-axis directions, X-axis feeding means 210 for moving the X-axis movable member 208 along the X-axis directions, a lifting and lowering block 212 vertically movably supported on the X-axis movable member 208, lifting and lowering means 214 for lifting and lowering the lifting and lowering block 212, an articulated arm 216 supported on the lifting and lowering block 212, a holder 218 vertically reversibly mounted on a distal end of the articulated arm 216, and an actuator, not illustrated, for actuating the articulated arm 216.

As illustrated in FIG. 9, the X-axis feeding means 210 that is supported on the support wall 206 has a ball screw 220 operatively threaded through a nut 220a fixed to the X-axis movable member 208 and extending along the X-axis directions, and a motor 222 for rotating the ball screw 220 about its central axis. The X-axis feeding means 210 moves the X-axis movable member 208 in the X-axis directions along a pair of guide rails 206a on the support wall 206. The lifting and lowering means 214 that is supported on the X-axis movable member 208 has a ball screw 224 coupled to the lifting and lowering block 212 and extending along the Z-axis directions and a motor 226 for rotating the ball screw 224 about its central axis. The lifting and lowering means 214 lifts and lowers the lifting and lowering block 212 along a pair of guide rails 208a of the X-axis movable member 208. The actuator, which may be actuated pneumatically or electrically, actuates the articulated arm 216 to position the holder 218 at any position in each of the X-, Y-, and Z-axis directions and to vertically reverse the holder 218, i.e., to turn the holder 218 upside down. The holder 218 has a plurality of suction holes, not illustrated, defined in one surface thereof and connected to suction means, not illustrated.

The storing means 202 operates in the following manner. The suction holes in the holder 218 are directed downwardly, and the suction means generates and applies a suction force to the holder 218 through the suction holes to hold under suction a wafer supported on the wafer support portion 118 of a tray 9. The lifting and lowering block 212 is moved by the X-axis feeding means 210 and the lifting and lowering means 214 to bring the holder 218 into a position aligned with a cassette 198 housed in the cassette stocker 200. The wafer held under suction on the holder 218 is then stored into the cassette 198 in the cassette stocker 200.

The quality inspecting unit 13 will be described below with reference to FIGS. 1, 17A through 17C, and 18A through 18C. As illustrated in FIG. 1, the quality inspecting unit 13 according to the present embodiment includes an ingot quality inspecting unit 300 for inspecting the quality of an ingot and a wafer quality inspecting unit 302 for inspecting the quality of a wafer peeled off from an ingot.

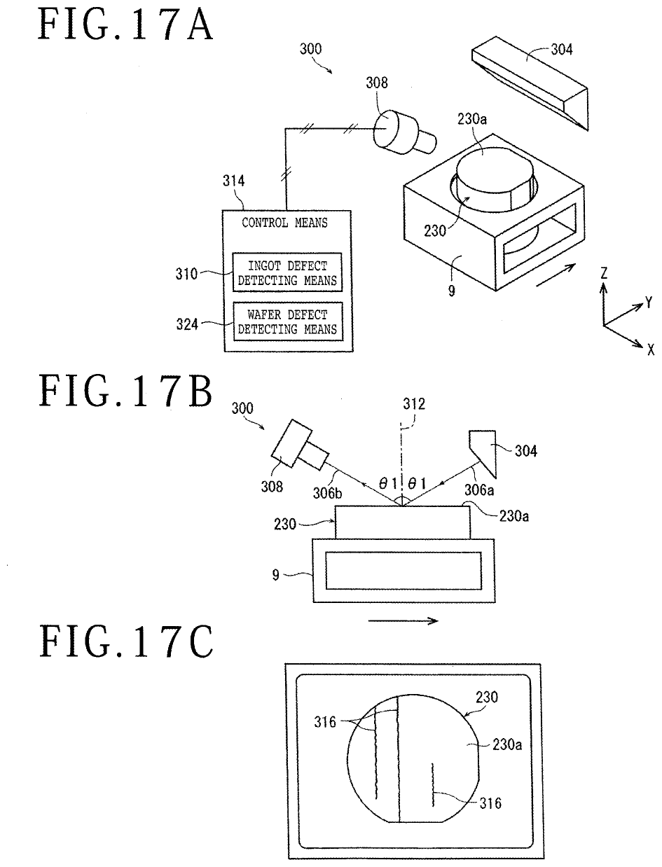

As illustrated in FIG. 1, the ingot quality inspecting unit 300 is disposed above the forward belt conveyors 121 between the tray stopper 129 at the position facing the ingot grinding unit 4 and the tray stopper 129 at the position facing the laser applying unit 6. The ingot quality inspecting unit 300 will be described in detail with reference to FIGS. 17A through 17C. The ingot quality inspecting unit 300 includes an illuminating device 304 for emitting light 306a (see FIG. 17B), image capturing means 308 for detecting reflected light 306b (see FIG. 17B) reflected by the upper surface of an ingot that is illuminated by the light 306a and capturing an image produced by the reflected light 306b, and ingot defect detecting means 310 for processing the image captured by the image capturing means 308 and detecting defects from the processed image.

The illuminating device 304 and the image capturing means 308 are spaced from each other along the delivering direction, i.e., the Y1 direction, of the forward belt conveyors 121, and are supported on a bracket, not illustrated. The light 306a emitted by the illuminating device 304 may be visible light. The image capturing means 308 may include a line sensor having a linear array of image capturing elements.

As illustrated in FIG. 17B, an angle θ1 formed between the light 306a from the illuminating device 304 and a line 312 normal to the upper surface of the ingot, i.e., an incident angle θ1, should desirably be an angle at which total reflection occurs from the upper surface of the ingot. However, the incident angle θ1 may be an angle sufficient for part of the light 306a from the illuminating device 304 to be reflected from the upper surface of the ingot and captured by the image capturing means 308.

The ingot defect detecting means 310 according to the present embodiment is included as part of control means 314, e.g., a computer, for controlling operation of the wafer manufacturing apparatus 2. The control means 314 is electrically connected to the image capturing means 308. Data of images captured by the image capturing means 308 are input to the ingot defect detecting means 310 of the control means 314. The ingot defect detecting means 310 processes an image captured by the image capturing means 308 and detects, from the processed image, defects on the upper surface of the ingot that may disrupt the pulsed laser beam LB applied from the laser applying unit 6 to the ingot. The defects on the upper surface of the ingot may be linear marks 316 (see FIG. 17C) formed on the upper surface of the ingot upon peeling off of a wafer from the ingot, for example.

The wafer manufacturing apparatus 2 according to the present embodiment includes the single ingot quality inspecting unit 300. However, the wafer manufacturing apparatus may include a first ingot quality inspecting unit for inspecting the quality of an ingot that has been roughly ground by an ingot grinding unit for rough grinding and a second ingot quality inspecting unit for inspecting the quality of an ingot that has been finishingly ground by an ingot grinding unit for finishing grinding. The first and second ingot quality inspecting units may be of the same arrangement as the ingot quality inspecting unit 300 described above.

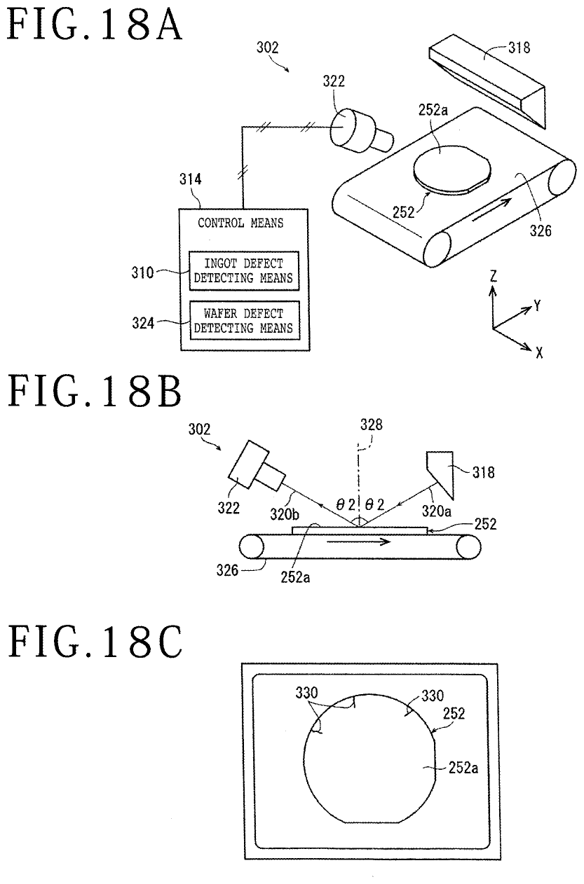

As illustrated in FIG. 1, the wafer quality inspecting unit 302 is disposed adjacent to the downstream end of the most downstream forward belt conveyor 121 in the Y1 direction and the wafer peeling unit 8. The wafer quality inspecting unit 302 will be described in detail with reference to FIGS. 18A through 18C. The wafer quality inspecting unit 302 includes an illuminating device 318 for emitting light 320a (see FIG. 18B), image capturing means 322 for detecting reflected light 320b (see FIG. 18B) reflected by the upper surface of a wafer that is illuminated by the light 320a and capturing an image produced by the reflected light 320b, wafer defect detecting means 324 for processing the image captured by the image capturing means 322 and detecting defects from the processed image, and a wafer belt conveyor 326 for moving a wafer while the image capturing means 322 is capturing an image of the wafer.

The illuminating device 318 and the image capturing means 322 are spaced from each other along a delivering direction of the wafer belt conveyor 326 (Y-axis directions in the present embodiment), and are supported on a bracket, not illustrated. The light 320a emitted by the illuminating device 318 may be visible light. The image capturing means 322 may include a line sensor having a linear array of image capturing elements. An angle θ2 formed between the light 320a from the illuminating device 318 and a line 328 normal to the upper surface of the wafer, i.e., an incident angle θ2, is set to an angle at which total reflection essentially occurs from the upper surface of the wafer. The wafer belt conveyor 326 has its delivering direction switchable between the Y1 direction and the Y2 direction.

The wafer defect detecting means 324 according to the present embodiment is included as part of the control means 314, as with the ingot defect detecting means 310. Data of images captured by the image capturing means 322 are input to the wafer defect detecting means 324 of the control means 314. The wafer defect detecting means 324 processes an image captured by the image capturing means 322 and detects, from the processed image, defects on the upper surface of the wafer, such as cracks 330 as illustrated in FIG. 18C.

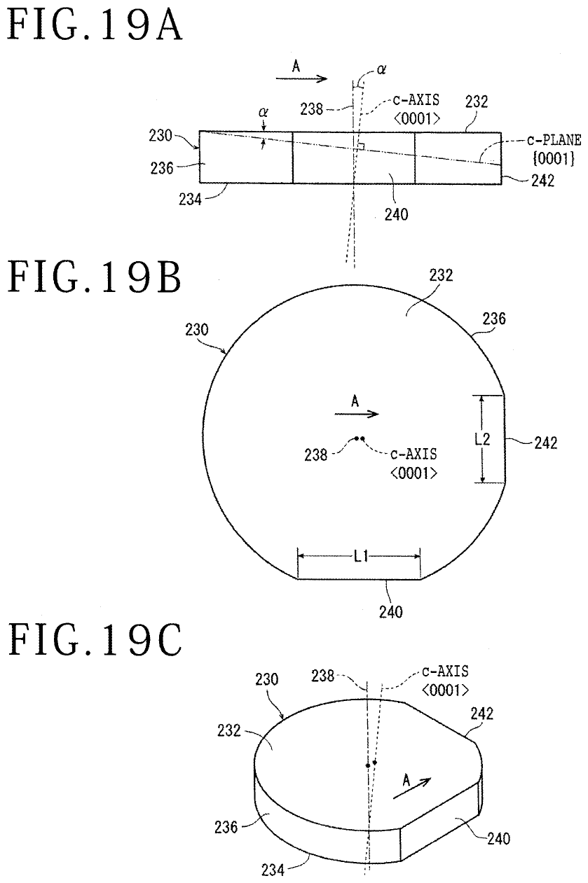

FIGS. 19A through 19C illustrate an ingot 230 to be processed by the wafer manufacturing apparatus 2. The illustrated ingot 230 is made of hexagonal single-crystal SiC and has a cylindrical shape as a whole. The single-crystal SiC ingot 230 has a circular first face 232, a circular second face 234 opposite the first face 232, a peripheral face 236 positioned between the first face 232 and the second face 234, a c-axis (<0001> direction) extending from the first face 232 to the second face 234, and a c-plane ({0001} plane) perpendicular to the c-axis.

In the illustrated ingot 230, the c-axis is inclined to a line 238 normal to the first face 232, and the c-plane and the first face 232 form an off-angle α (e.g., α=1, 3, or 6 degrees) therebetween. A direction in which the off-angle α is formed is indicated by an arrow A in FIGS. 19A through 19C. The peripheral face 236 of the single-crystal SiC ingot 230 has a first orientation flat 240 and a second orientation flat 242, each of a rectangular shape, for indicating a crystal orientation. The first orientation flat 240 lies parallel to the direction A in which the off-angle α is formed, whereas the second orientation flat 242 lies perpendicularly to the direction A in which the off-angle α is formed. As illustrated in FIG. 19B, a length L2 of the second orientation flat 242 is smaller than a length L1 of the first orientation flat 240, as viewed from above (L2<L1).

The ingot that can be processed by the wafer manufacturing apparatus 2 is not limited to the above single-crystal SiC ingot 230, but may be a single-crystal SiC ingot where the c-axis is not inclined to the line normal to the first face and the off-angle between the c-plane and the first face is 0 degrees (i.e., the line normal to the first face coincides with the c-axis) or an ingot made of a material other than single-crystal SiC, such as Si or gallium nitride (GaN).

For manufacturing wafers from ingots 230 on the wafer manufacturing apparatus 2 described above, an ingot accommodating step is carried out to accommodate the ingots 230 into the ingot stocker 11. Specifically, in the ingot accommodating step according to the present embodiment, first, four ingots 230 are prepared and supported on the respective ingot support portions 117 of four trays 9. Then, the trays 9 with the ingots 230 supported therein are placed on the respective rest tables 146 of the ingot stocker 11 and hence accommodated in the ingot stocker 11.

After the ingot accommodating step has been carried out, a first delivering step for delivering the ingots 230 from the ingot stocker 11 to the laser applying unit 6 is performed by the ingot transfer unit 12 and the belt conveyor unit 10. The end faces, i.e., the first face 232 and the second face 234, of each of the ingots 230 have been planarized to an extent that they will not disturb entry of a laser beam in a peel-off layer forming step to be described later. According to the present embodiment, therefore, the ingots 230 are delivered from the ingot stocker 11 to the laser applying unit 6 in the first delivering step. However, in a case where the end faces of the ingots have not been planarized to the extent that they will not disturb the entry of a laser beam in the peel-off layer forming step, the ingots may be delivered from the ingot stocker 11 to the ingot grinding unit 4 in the first delivering step.

In the first delivering step, the lifting and lowering plate 186 of the elevator 168 in the ingot transfer unit 12 is lifted or lowered and positioned in a position where the upper surface of the rest table 146 located at any position, e.g., the uppermost position, in the ingot stocker 11 and the upper surface of the receiving table 160 lie flush with each other. Then, the air cylinder 174 of the clutch assembly 166 is actuated to insert one of the tapered pins 178 of the clutch assembly 166 into the drive force transmitter 150 of the ingot stocker 11 and also to insert the other tapered pin 178 into the drive force transmitter 172 of the ingot transfer unit 12. Then, the motor 164 of the ingot transfer unit 12 is energized to actuate the second endless belts 162 in the receiving table 160 and the first endless belt 148 in the rest table 146. The tray 9 placed on the rest table 146 is now fed from the rest table 146 in the Y1 direction by the first endless belt 148 and transferred onto the receiving table 160 of the ingot transfer unit 12.

After the tray 9 has been transferred to the receiving table 160, the motor 164 is de-energized. The piston rod 174b of the air cylinder 174 is moved from the retracted position to the extended position, thereby uncoupling the one of the tapered pins 178 from the drive force transmitter 150 of the ingot stocker 11 and also uncoupling the other tapered pin 178 from the drive force transmitter 172 of the ingot transfer unit 12. Then, the lifting and lowering plate 186 of the elevator 168 is moved to align the upper surface of the receiving table 160 with the tray 9 placed thereon with the upper surfaces of the endless belts 127 of the forward belt conveyors 121 of the belt conveyor unit 10. Then, the motor 164 is energized to actuate the second endless belts 162 to thereby transfer the tray 9 on the upper surface of the receiving table 160 onto the most upstream forward belt conveyor 121.

After the tray 9 has been transferred to the most upstream forward belt conveyor 121, the tray 9 is delivered to a position facing the laser applying unit 6 by the forward belt conveyors 121. At this time, the lifting and lowering plate 131 of the tray stopper 129 disposed in the position facing the ingot grinding unit 4 is positioned in the passing position, and the lifting and lowering plate 131 of the tray stopper 129 disposed in the position facing the laser applying unit 6 is positioned in the stopping position. Therefore, the tray 9 that is delivered in the Y1 direction by the forward belt conveyors 121 passes over the tray stopper 129 disposed in the position facing the ingot grinding unit 4, and is stopped by the tray stopper 129 disposed in the position facing the laser applying unit 6.

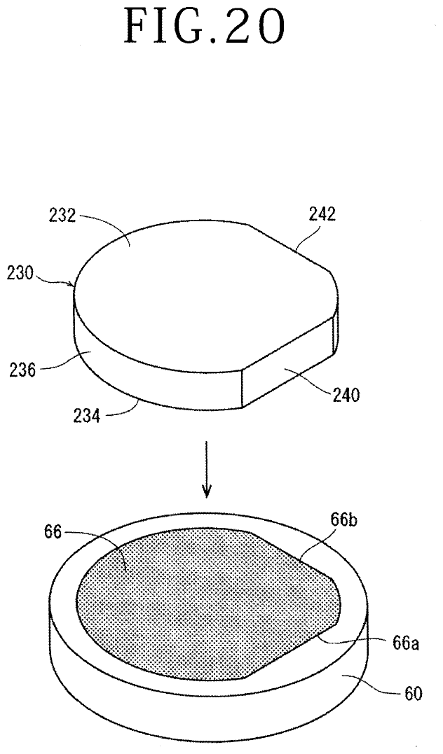

Then, in order to space the lower surface of the stopped tray 9 from the upper surface of the endless belts 127, the lifting and lowering plate 131 of the tray stopper 129 is lifted to the spacing position. Then, the articulated arm 144 of the second transferring means 142 is actuated to bring the suction member 145 into intimate contact with the upper surface, i.e., the first face 232 according to the present embodiment, of the ingot 230. Then, the suction means connected to the suction member 145 is actuated to generate and apply a suction force to the suction member 145, which holds the ingot 230 under suction. Then, the articulated arm 144 moves the suction member 145 until the lower surface, i.e., the second face 234 according to the present embodiment, of the ingot 230 held under suction on the suction member 145 contacts the upper surface of the second holding table 60 of the laser applying unit 6, as illustrated in FIG. 20. At this time, the second holding table 60 is positioned in an ingot mounting/dismounting position illustrated in FIG. 4 for mounting and dismounting an ingot.

As illustrated in FIG. 20, the suction chuck 66 that is of a circular shape according to the present embodiment has a first straight edge 66a corresponding to the first orientation flat 240 of the ingot 230 and a second straight edge 66b corresponding to the second orientation flat 242 of the ingot 230. The suction chuck 66 is capable of holding under a predetermined suction force the ingot 230 that has the first orientation flat 240 and the second orientation flat 242. The suction means connected to the suction member 145 is inactivated to cancel the suction force applied to the suction member 145, releasing the ingot 230 on the upper surface of the second holding table 60. In this manner, the first delivering step for delivering the ingot 230 from the ingot stocker 11 to the laser applying unit 6 is performed. Although not illustrated, each of the suction chucks 22 of the first holding tables 14 of the ingot grinding unit 4 and the suction chuck 86 of the third holding table 80 of the wafer peeling unit 8 also has a first straight edge corresponding to the first orientation flat 240 of the ingot 230 and a second straight edge corresponding to the second orientation flat 242 of the ingot 230.

After the first delivering step has been carried out, the laser applying unit 6 performs a peel-off layer forming step in which the second holding table 60 holds the ingot 230 thereon and the laser applying means 62 applies a laser beam having a wavelength transmittable through the ingot 230 to the ingot 230, forming peel-off layers in the ingot 230 while positioning the focused spot of the laser beam at a depth, which corresponds to the thickness of a wafer to be produced from the ingot 230, from the upper surface of the ingot 230 held on the second holding table 60.

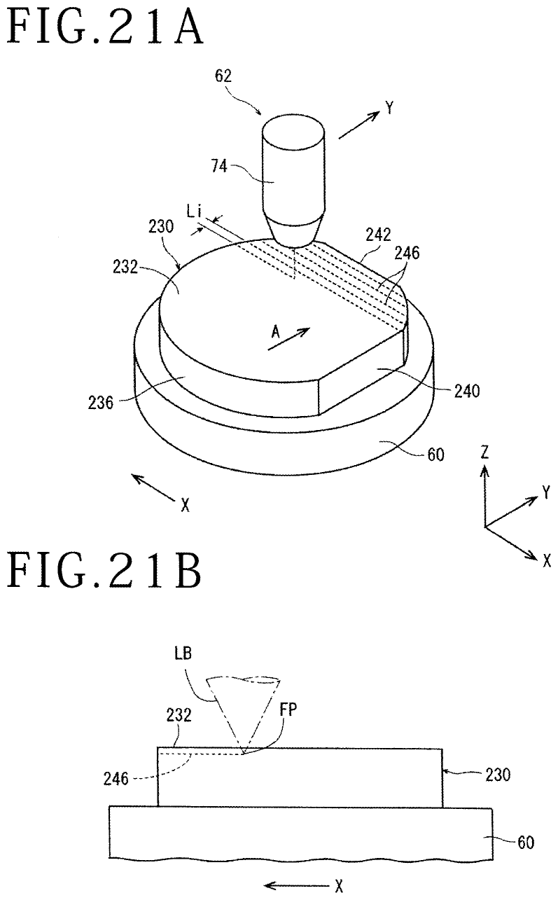

In the peel-off layer forming step, a suction force is applied to the upper surface of the second holding table 60, holding the ingot 230 under suction on the second holding table 60. Then, the X-axis feeding means moves the second holding table 60 in one of the X-axis directions, and the Y-axis feeding means moves the second holding table 60 in one of the Y-axis directions, thereby positioning the ingot 230 on the second holding table 60 beneath the alignment means 76. Then, the alignment means 76 captures an image of the ingot 230 from above the ingot 230. Then, on the basis of the image of the ingot 230 captured by the alignment means 76, the second holding table motor and the X-axis feeding means rotate and move the second holding table 60, and the Y-axis feeding means moves the Y-axis movable member, thereby adjusting the orientation of the ingot 230 to a predetermined orientation and adjusting the positions of the ingot 230 and the beam condenser 74 in an XY plane that is defined jointly by the X- and Y-axis directions. In order to adjust the orientation of the ingot 230 to a predetermined orientation, as illustrated in FIG. 21A, the second orientation flat 242 is directed to face in the X-axis directions to thereby align the direction perpendicular to the direction A in which the off-angle α is formed with the X-axis directions and to align the direction A in which the off-angle α is formed with the Y-axis directions.

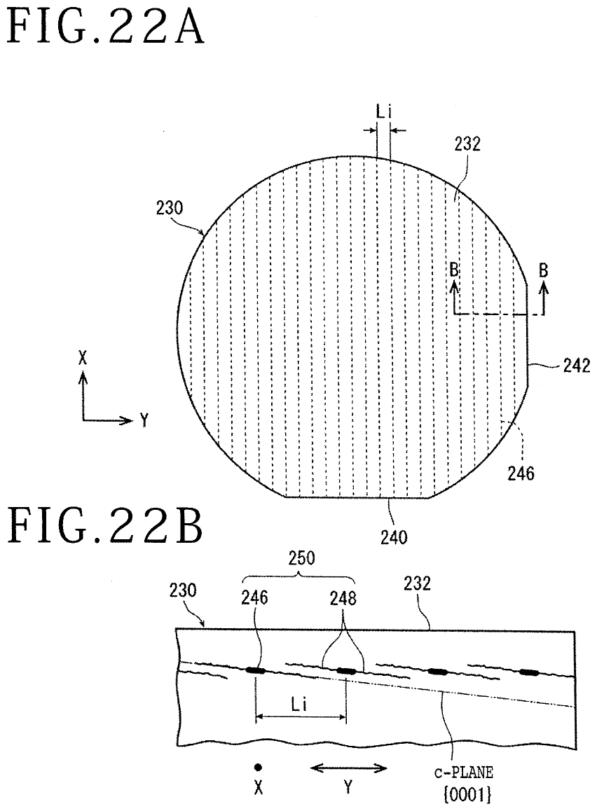

Then, the focused spot position adjusting means lifts or lowers the beam condenser 74 to position the focused spot, denoted by FP in FIG. 21B, of the pulsed laser beam LB at the depth, which corresponds to the thickness of a wafer to be produced from the ingot 230, from the first face 232 of the ingot 230. Then, while the X-axis feeding means is moving the second holding table 60 in one of the X-directions that is aligned with the direction perpendicular to the direction A in which the off-angle α is formed, the beam condenser 74 applies the pulsed laser beam LB whose wavelength is transmittable through the ingot 230 to the ingot 230. Now, as illustrated in FIGS. 22A and 22B, the applied pulsed laser beam LB separates SiC into Si and C (carbon), and the subsequently applied pulsed laser beam LB is absorbed by the previously formed C. SiC is successively separated into Si and C in a region 246, also referred to as a separated region 246, and at the same time, a succession of cracks 248 extending isotropically along the c-plane from the separated region 246 are developed in the ingot 230.

Then, the Y-axis feeding means moves the Y-axis movable member to indexing-feed the focused spot FP relatively to the ingot 230 by a predetermined indexing distance L1 not exceeding the width of the cracks 248 in one of the Y-axis directions aligned with the direction A in which the off-angle α is formed. The application of the pulsed laser beam LB and the indexing-feeding of the focused spot FP are alternately repeated to form a plurality of separated regions 246 that continuously extend in the direction perpendicular to the direction A in which the off-angle α is formed and are spaced apart by the predetermined indexing distance L1 in the direction A in which the off-angle α is formed, and to form a succession of cracks 248 extending isotropically along the c-plane from the separated regions 246, such that the cracks 248 that are disposed adjacent to each other in the direction A in which the off-angle α is formed overlap each other vertically. In this manner, peel-off layers 250, each made up of the separated region 246 and the cracks 248, whose mechanical strength has been reduced for peeling off a wafer from the ingot 230, are formed in the ingot 230 at a depth corresponding to the thickness of the wafer to be produced from the ingot 230. After the peel-off layers 250 have been formed in the ingot 230, the second holding table 60 is positioned in the ingot mounting/dismounting position, and the suction force applied to the second holding table 60 is canceled. The peel-off layer forming step may be carried out under the following processing conditions, for example:

Wavelength of pulsed laser beam: 1064 nm

Repetitive frequency: 80 kHz

Average output power: 3.2 W

Pulse duration: 4 ns

Diameter of focused spot: 3 μm

Numerical aperture (NA) of condensing lens: 0.43

Position of focused spot in Z-axis directions: 300 μm from upper surface of ingot

Feeding speed of second holding table: 120 to 260 mm/s

Indexing distance: 250 to 400 μm

After the peel-off layer forming step has been carried out, a second delivering step for delivering the ingot 230 with the peel-off layers 250 formed therein from the laser applying unit 6 to the wafer peeling unit 8 is carried out by the belt conveyor unit 10. In the second delivering step, the articulated arm 144 of the second transferring means 142 is actuated to bring the suction member 145 into intimate contact with the first face 232 of the ingot 230 on the second holding table 60, and the suction member 145 holds the ingot 230 under suction thereon. Then, the articulated arm 144 moves the suction member 145 to bring the second face 234 of the ingot 230 held under suction on the suction member 145 into contact with the ingot support portion 117 of the tray 9. Then, the suction force applied to the suction member 145 is canceled, allowing the ingot support portion 117 of the tray 9 to support the ingot 230. Then, the lifting and lowering plate 131 of the tray stopper 129 is lowered from the spacing position to the passing position, placing the tray 9 onto the endless belts 127 of the middle forward belt conveyor 121.

After the tray 9 has been placed on the middle forward belt conveyor 121, the forward belt conveyors 121 deliver the tray 9 to the position facing the wafer peeling unit 8, i.e., the end point of the forward belt conveyors 121 according to the present embodiment. At this time, the lifting and lowering plate 135 is positioned at a height where the upper surface of the Y-axis movable plate 137 is lower than the upper surfaces of the endless belts 127 of the forward belt conveyors 121 and the stopper piece 138 contacts the tray 9 delivered by the forward belt conveyors 121, and the Y-axis movable plate 137 is positioned in the advanced position. The stopper piece 138 can now be brought into contact with the tray 9 being delivered by the most downstream forward belt conveyor 121 in the Y1 direction, stopping the tray 9 at the position facing the wafer peeling unit 8.

Then, the lifting and lowering plate 135 of the delivery means 123 is lifted to place the stopped tray 9 on the upper surface of the Y-axis movable plate 137 and to space the lower surface of the tray 9 from the upper surfaces of the endless belts 127. Then, the articulated arm 144 of the third transferring means 143 is actuated to bring the suction member 145 into intimate contact with the first face 232 of the ingot 230, and the suction member 145 holds the ingot 230 under suction thereon. Then, the articulated arm 144 moves the suction member 145 to bring the second face 234 of the ingot 230 held under suction on the suction member 145 into contact with the upper surface of the third holding table 80 of the wafer peeling unit 8. At this time, the third holding table 80 is positioned in an ingot mounting/dismounting position, i.e., the position illustrated in FIG. 6. Then, the suction force applied to the suction member 145 is canceled, allowing the ingot 230 to be placed onto the upper surface of the third holding table 80. In this fashion, the second delivering step for delivering the ingot 230 from the laser applying unit 6 to the wafer peeling unit 8 is carried out.

After the second delivering step has been carried out, a wafer peeling step for holding the ingot 230 with the peel-off layers 250 formed therein on the third holding table 80 and peeling off a wafer from the ingot 230 at the peel-off layers 250 therein is carried out by the wafer peeling unit 8.

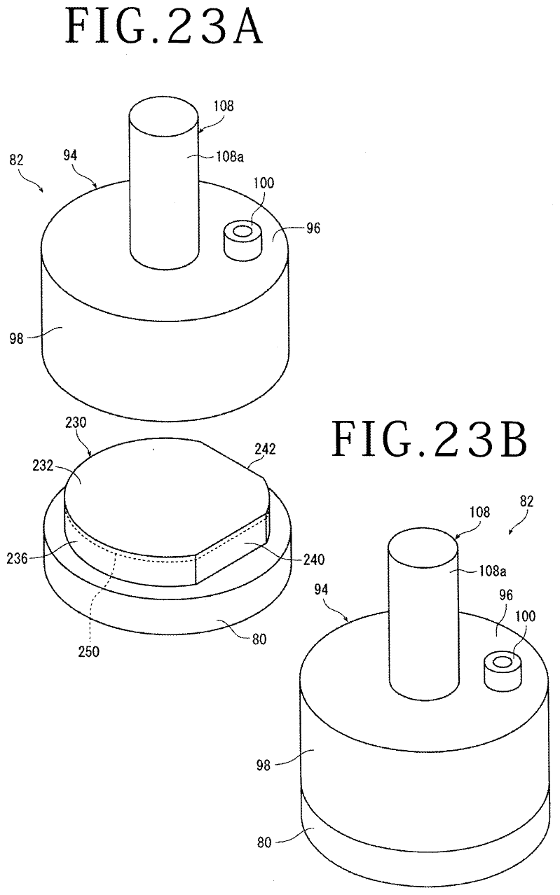

In the wafer peeling step, the third holding table 80 holds the ingot 230 under suction thereon. Then, as illustrated in FIG. 23A, the third holding table 80 is positioned in a wafer peeling position below the liquid tank 94. Then, the arm moving means lowers the arm 92 to bring the lower end of the skirt wall 98 of the liquid tank 94 into intimate contact with the upper surface of the third holding table 80, as illustrated in FIG. 23B.

Then, as illustrated in FIG. 7, the piston rod 108b of the air cylinder 108 is moved to bring the lower surface of the suction member 112 into intimate contact with the first face 232 of the ingot 230. Then, a suction force is applied to the lower surface of the suction member 112, which holds the ingot 230 under suction from the side of the first face 232. Then, the liquid supply means connected to the liquid supply member 100 is actuated to introduce the liquid 106, such as water, from the liquid supply member 100 into the liquid accommodating space 104 until the ultrasonic vibration generator 110 is immersed in the liquid 106. Then, the ultrasonic vibration generator 110 is actuated to apply ultrasonic vibrations to the ingot 230, stimulating the peel-off layers 250 to extend the cracks 248, to thereby further reduce the mechanical strength of the peel-off layers 250.

Then, while the suction member 112 is holding the ingot 230 under suction thereon, the arm moving means lifts the arm 92 to peel off a disk-shaped ingot portion over the peel-off layers 250 as a wafer 252 from the ingot 230 at the peel-off layers 250 as severance initiating points. When the arm 92 is lifted, the liquid 106 is drained from the liquid accommodating space 104 and discharged out of the wafer peeling unit 8 through a drain port, not illustrated, defined in the base 84. After the wafer 252 has been peeled off from the ingot 230, the third holding table 80 is positioned in the ingot mounting/dismounting position, and the suction force applied to the third holding table 80 is canceled. When ultrasonic vibrations are applied to the ingot 230, a clearance ranging from 2 to 3 mm, for example, may be provided between the upper surface of the ingot 230 and the lower surface of the suction member 112. When the wafer 252 is peeled off from the ingot 230 at the peel-off layers 250 as the severance initiating points, the suction member 145 may be lifted to peel off the wafer 252 from the ingot 230 while the suction member 145 of the third transferring means 143 is holding the upper surface of the ingot 230 under suction.

After the wafer peeling step has been carried out, a wafer quality inspecting step for inspecting whether or not defects exist in the wafer 252 peeled off from the ingot 230 is carried out by the wafer quality inspecting unit 302.

In the wafer quality inspecting step, the articulated arm 144 of the third transferring means 143 is actuated to bring the suction member 145 thereof into intimate contact with an upper surface 252a, which is opposite a peeled-off surface 252b having surface irregularities, of the wafer 252 attracted to the suction member 112 of the wafer peeling means 82, and the suction member 145 holds the wafer 252 under suction thereon. Then, the suction force applied to the suction member 112 of the wafer peeling means 82 is canceled, transferring the wafer 252 from the suction member 112 of the wafer peeling means 82 to the suction member 145 of the third transferring means 143. Then, the articulated arm 144 moves the suction member 145, bringing the wafer 252 that is held under suction on the suction member 145 into contact with the wafer belt conveyor 326 while the peeled-off surface 252b of the wafer 252 is facing downwardly. Then, the suction force applied to the suction member 145 is canceled, allowing the wafer belt conveyor 326 to support the wafer 252.

Then, as illustrated in FIGS. 18A and 18B, while the wafer 252 is being delivered by the wafer belt conveyor 326, the illuminating device 318 emits and applies light 320a to the upper surface 252a of the wafer 252, and the image capturing means 322 detects reflected light 320b from the upper surface 252a that is illuminated by the light 320a, and captures an image produced by the reflected light 320b. When the image capturing means 322 has captured an image of the entire upper surface 252a of the wafer 252, the wafer belt conveyor 326 is stopped. The wafer defect detecting means 324 processes the image captured by the image capturing means 322 and determines whether or not defects such as cracks 330 (see FIG. 18C) exist in the wafer 252 on the basis of the processed image.

If no defects are detected in the wafer 252, then a third delivering step for delivering the wafer 252 from the wafer quality inspecting unit 302 to and placing the wafer 252 in one of the cassettes 198 in the cassette stocker 200 is carried out by the belt conveyor unit 10, the ingot transfer unit 12, and the storing means 202. If defects are detected in the wafer 252, then the wafer 252 with the detected defects is discarded. For example, a wafer retrieval box, not illustrated, may be provided at a downstream end of the wafer belt conveyor 326 in the delivering direction thereof, and the wafer 252 with the detected defects may be delivered to and placed in the wafer retrieval box by the wafer belt conveyor 326. In the wafer manufacturing apparatus 2 according to the present embodiment, therefore, since wafers 252 with detected defects are discarded without being delivered to a next step, the quality of wafers 252 manufactured by the wafer manufacturing apparatus 2 maintains a certain standard.

In the third delivering step, the articulated arm 144 of the third transferring means 143 is actuated to bring the suction member 145 of the third transferring means 143 into intimate contact with the upper surface 252a of the wafer 252 on the wafer belt conveyor 326, and the suction member 145 holds the wafer 252 under suction thereon. Then, the suction force applied to the suction member 112 of the wafer peeling means 82 is canceled, transferring the wafer 252 from the suction member 112 of the wafer peeling means 82 to the suction member 145 of the third transferring means 143. Then, the articulated arm 144 moves the suction member 145, bringing the wafer 252 that is held under suction on the suction member 145 into contact with the wafer support portion 118 of a tray 9. Then, the suction force applied to the suction member 145 is canceled, allowing the wafer support portion 118 of the tray 9 to support the wafer 252.

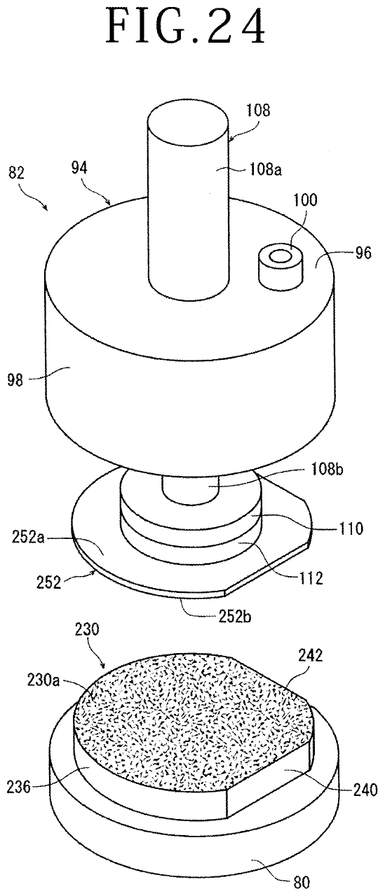

In the third delivering step, moreover, in order to deliver the wafer 252 and also to deliver the ingot 230 from which the wafer 252 has been peeled off from the wafer peeling unit 8 to the ingot grinding unit 4, the articulated arm 144 is actuated to bring the suction member 145 into intimate contact with a peeling surface 230a (see FIG. 24), from which the wafer 252 has been peeled off, of the ingot 230 on the third holding table 80, and the suction member 145 holds the ingot 230 under suction thereon. Then, the articulated arm 144 moves the suction member 145 to deliver the ingot 230 held under suction thereon to the ingot support portion 117 of the tray 9, which then supports the ingot 230. Then, the Y-axis movable plate 137 of the delivery means 123 that is carrying the tray 9 is positioned in the retracted position. Then, the lifting and lowering plate 135 is lowered to position the upper surface of the Y-axis movable plate 137 slightly above the upper surfaces of the endless belts 127 of the return belt conveyors 122. Then, the Y-axis movable plate 137 is positioned in the advanced position, and the lifting and lowering plate 135 is lowered to place the tray 9 on the endless belts 127 of the most upstream return belt conveyor 122.

After the tray 9 has been placed on the most upstream return belt conveyor 122, the return belt conveyors 122 deliver the tray 9 to the endpoint thereof. At this time, the elevator 168 of the ingot transfer unit 12 aligns the upper surface of the receiving table 160 with the upper surfaces of the endless belts 127 of the return belt conveyors 122, and the motor 164 is energized to rotate the second endless belts 162 to move the upper surfaces thereof in the Y2 direction. The tray 9 that has been delivered in the Y2 direction by the return belt conveyors 122 is thus placed onto the upper surface of the receiving table 160.

After the tray 9 has been placed on the receiving table 160, the motor 164 is de-energized and the lifting and lowering plate 186 of the elevator 168 is moved to bring the upper surface of the receiving table 160 that is carrying the tray 9 into alignment with the upper surfaces of the endless belts 127 of the forward belt conveyors 121 of the belt conveyor unit 10. At this time, the piston rod 174b of the air cylinder 174 is positioned in the retracted position in order not to disrupt the movement of the lifting and lowering plate 186. Then, the X-axis feeding means 210 and the lifting and lowering means 214 of the storing means 202 move the lifting and lowering block 212, and the articulated arm 216 is actuated to bring the holder 218 into intimate contact with the upper surface of the wafer 252 supported on the tray 9 on the receiving table 160, whereupon the holder 218 holds the wafer 252 under suction thereon. The X-axis feeding means 210, the lifting and lowering means 214, and the articulated arm 216 move the holder 218 to unload the wafer 252 held under suction on the holder 218 from the tray 9 and move the wafer 252 into the cassette 198 in the cassette stocker 200. Then, the suction force of the holder 218 is canceled. In this manner, the wafer 252 peeled off from the ingot 230 is delivered from the wafer peeling unit 8 to one of the cassettes 198 in the cassette stocker 200 and placed in the cassette 198.

After the wafer 252 has been unloaded from the tray 9, the second endless belts 162 are moved to transfer the tray 9 placed on the upper surface of the receiving table 160 to the most upstream forward belt conveyor 121, which delivers the tray 9. At this time, the lifting and lowering plate 131 of the tray stopper 129 disposed in the position facing the ingot grinding unit 4 is positioned in the stopping position. The tray 9 being delivered in the Y1 direction by the most upstream forward belt conveyor 121 can thus be stopped by the tray stopper 129 in the position facing the ingot grinding unit 4.

Then, in order to space the lower surface of the stopped tray 9 from the upper surfaces of the endless belts 127, the lifting and lowering plate 131 of the tray stopper 129 is lifted to the spacing position. Then, the articulated arm 144 of the first transferring means 141 is actuated to bring the suction member 145 into intimate contact with the peeling surface 230a of the ingot 230, and the suction member 145 holds the ingot 230 under suction thereon. Then, the articulated arm 144 moves the suction member 145 to bring the second face 234 of the ingot 230 into contact with the upper surface of the first holding table 14 positioned in the ingot mounting/dismounting position in the ingot grinding unit 4. Then, the suction force applied to the suction member 145 is canceled, placing the ingot 230 on the upper surface of the first holding table 14. In this fashion, the ingot 230 from which the wafer 252 has been peeled off is delivered from the wafer peeling unit 8 to the ingot grinding unit 4.

After the third delivering step has been carried out, an ingot grinding step for holding the ingot 230 from which the wafer 252 has been peeled off on the first holding table 14 and grinding the peeling surface 230a of the ingot 230 held on the first holding table 14 to planarize the peeling surface 230a is carried out by the ingot grinding unit 4.

In the ingot grinding step, as illustrated in FIG. 3, a suction force is applied to the upper surface of the first holding table 14, causing the first holding table 14 to hold the ingot 230 under suction thereon. Then, the first holding table 14 that is holding the ingot 230 thereon is positioned in the grinding position. Then, the first holding table 14 that is holding the ingot 230 thereon is rotated about its central axis counterclockwise as viewed from above at a predetermined rotational speed of 300 rpm, for example. Further, the spindle 36 is rotated about its central axis counterclockwise as viewed from above at a predetermined rotational speed of 6000 rpm, for example. Then, the spindle housing 30 is lowered to bring the grindstones 44 into contact with the peeling surface 230a of the ingot 230. Thereafter, the spindle housing 30 is lowered at a predetermined grinding feed speed of 1.0 μm/s, for example. In this manner, the peeling surface 230a of the ingot 230 from which the wafer 252 has been peeled off is ground and planarized to the extent that it will not disturb the entry of the pulsed laser beam LB in the peel-off layer forming step. After the peeling surface 230a of the ingot 230 has been planarized, the first holding table 14 that is holding the ingot 230 thereon is positioned in the ingot mounting/dismounting position, and the suction force applied to the first holding table 14 is canceled.

After the ingot grinding step has been carried out, an ingot quality inspecting step for inspecting whether or not defects that tend to disturb the entry of a laser beam in the peel-off layer forming step exist in the peeling surface 230a of the ingot 230, i.e., the upper surface of the ingot 230, is carried out by the ingot quality inspecting unit 300.

In the ingot quality inspecting step, the articulated arm 144 of the first transferring means 141 is actuated to bring the suction member 145 into intimate contact with the peeling surface 230a of the ingot 230 on the first holding table 14, and the suction member 145 holds the ingot 230 under suction thereon. Then, the articulated arm 144 moves the suction member 145 until the second face 234 of the ingot 230 held under suction on the suction member 145 contacts the ingot support portion 117 of a tray 9. Then, the suction force applied to the suction member 145 is canceled, allowing the ingot 230 to be supported on the ingot support portion 117 of the tray 9. Then, the lifting and lowering plate 131 of the tray stopper 129 is lowered from the spacing position to the passing position, placing the tray 9 on the endless belts 127 of the most upstream forward belt conveyor 121.

Then, as illustrated in FIGS. 17A and 17B, while the tray 9 is being delivered by the forward belt conveyors 121, the illuminating device 304 emits and applies the light 306a to the planarized peeling surface 230a of the ingot 230, i.e., the upper surface of the ingot 230, and the image capturing means 308 detects reflected light 306b from the peeling surface 230a that is illuminated by the light 306a and captures an image of the entire peeling surface 230a produced by the reflected light 306b. The ingot defect detecting means 310 processes the image captured by the image capturing means 308 and determines whether or not defects that tend to prevent required peel-off layers from being formed exist in the peeling surface 230a of the ingot 230 on the basis of the processed image.

If the ingot defect detecting means 310 does not detect defects in the ingot 230, then the peel-off layer forming step, the wafer peeling step, and the ingot grinding step described above are performed on the ingot 230 with no detected defects. If the peeling surface 230a of the ingot 230 has not been sufficiently planarized and the ingot defect detecting means 310 has determined that defects that tend to disturb the entry of the pulsed laser beam LB in the peel-off layer forming step exists in the peeling surface 230a of the ingot 230, then the peel-off layer forming step and the wafer peeling step are not performed on the ingot 230 with the detected defects. The ingot 230 with the detected defects is delivered by the belt conveyor unit 10 and the ingot transfer unit 12 to the ingot grinding unit 4, which performs the ingot grinding step again on the ingot 230. Thereafter, the ingot quality inspecting step is performed again on the ingot 230.

Inasmuch as the wafer manufacturing apparatus 2 according to the present embodiment does not perform the peel-off layer forming step and the wafer peeling step on the ingot 230 with the detected defects, the wafer 252 peeled off from the ingot 230 is prevented from having defects that would otherwise be developed if the focused spot FP of the pulsed laser beam LB were not positioned in proper positions in the ingot 230 and required peel-off layers were not formed in the ingot 230.

In the case where the wafer manufacturing apparatus includes an ingot grinding unit having grindstones for rough grinding and an ingot grinding unit having grindstones for finishing grinding, the wafer manufacturing apparatus may include a first ingot quality inspecting unit for inspecting whether or not surface roughness of the peeling surface 230a of a roughly ground ingot 230 has reached a predetermined surface roughness level and a second ingot quality inspecting unit for inspecting whether or not defects that tend to disturb the entry of a laser beam in the peel-off layer forming step exist in the peeling surface 230a of an finishingly ground ingot 230.

The peel-off layer forming step, the wafer peeling step, the wafer quality inspecting step, the ingot grinding step, and the ingot quality inspecting step are repeatedly carried out to manufacture as many wafers 252 as can be produced from the ingot 230, and the manufactured wafers 252 are accommodated in the cassettes 198 in the cassette stocker 200.

According to the present embodiment described above, it has been described that the wafer manufacturing apparatus 2 performs the above steps on a single ingot 230. Actually, however, the wafer manufacturing apparatus 2 performs the first delivering step for delivering an ingot 230 from the ingot stocker 11 to the laser applying unit 6, thereafter repeatedly performs the first delivering step at appropriate intervals, then repeatedly performs the peel-off layer forming step, the wafer peeling step, the ingot grinding step, and the ingot quality inspecting step concurrently on a plurality of, four in the present embodiment, ingots 230, and performs the wafer quality inspecting step on a wafer 252 peeled off from each of the ingots 230, thereby manufacturing as many wafers 252 as can be produced from the ingots 230.

As described above, since the wafer manufacturing apparatus 2 according to the present embodiment includes the ingot quality inspecting unit 300 and the wafer quality inspecting unit 302, the quality of wafers 252 manufactured from ingots 230 is prevented from being lowered.

According to the present embodiment, the wafer manufacturing apparatus 2 that includes the ingot quality inspecting unit 300 and the wafer quality inspecting unit 302 has been illustrated as a preferred example. However, the wafer manufacturing apparatus according to the present invention may include either one of the ingot quality inspecting unit 300 and the wafer quality inspecting unit 302.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A wafer manufacturing apparatus for manufacturing a wafer from a semiconductor ingot, comprising:
an ingot grinding unit including a first holding table for holding the semiconductor ingot thereon and grinding means for grinding an upper surface of the semiconductor ingot held on the first holding table to planarize the upper surface of the semiconductor ingot;
a laser applying unit including a second holding table for holding the semiconductor ingot thereon and laser applying means for applying a laser beam having a wavelength transmittable through the semiconductor ingot while positioning a focused spot of the laser beam at a depth in the ingot, the depth corresponding to a thickness of the wafer to be produced from the semiconductor ingot, from the upper surface of the semiconductor ingot held on the second holding table, thereby forming peel-off layers in the semiconductor ingot;
a wafer peeling unit including a third holding table for holding the semiconductor ingot thereon and wafer peeling means for holding the upper surface of the semiconductor ingot held on the third holding table and peeling an ingot portion as the wafer from the ingot at the peel-off layers;
a tray including an ingot support portion for supporting the semiconductor ingot and a wafer support portion for supporting the wafer that has been peeled off from the semiconductor ingot;
a belt conveyor unit for delivering the semiconductor ingot supported on the tray between the ingot grinding unit, the laser applying unit, and the wafer peeling unit; and
a quality inspecting unit disposed adjacent to the belt conveyor unit.

2. The wafer manufacturing apparatus according to claim 1, wherein the quality inspecting unit includes an illuminating device, image capturing means for detecting reflected light reflected by an upper surface of the wafer that is illuminated by light emitted from the illuminating device, and defect detecting means for processing an image captured by the image capturing means and detecting a defect from the processed image.

3. The wafer manufacturing apparatus according to claim 1, wherein the quality inspecting unit includes an illuminating device, image capturing means for detecting reflected light reflected by an upper surface of the semiconductor ingot that is illuminated by light emitted from the illuminating device, and defect detecting means for processing an image captured by the image capturing means and detecting a defect from the processed image.
